(19) United States
(12) Patent Application Publication
(10) Pub. No.: US 2025/0125262 A1
(43) Pub. Date: Apr. 17, 2025

(54) IC STRUCTURE WITH HIGH THERMAL CONDUCTIVITY LAYER ON SEMICONDUCTOR DEVICES

(71) Applicant: Taiwan Semiconductor Manufacturing Company, Ltd., Hsinchu (TW)

(72) Inventors: Che Chi Shih, Taoyuan City (TW); Tsung-Kai Chiu, Hsinchu County (TW); Ku-Feng Yang, Baoshan Township (TW); Wei-Yen Woon, Taoyuan City (TW); Szuya Liao, Hsinchu (TW)

(21) Appl. No.: 18/591,282

(22) Filed: Feb. 29, 2024

Related U.S. Application Data
(60) Provisional application No. 63/589,715, filed on Oct. 12, 2023.

(51) Int. Cl. H01L 23/528; H01L 21/8234; H01L 23/373; H01L 23/532; H01L 27/088; H01L 29/06; H01L 29/417; H01L 29/423; H01L 29/775; H01L 29/786

(52) U.S. Cl. CPC H01L 23/5283; H01L 23/3732; H01L 23/3735; H01L 23/53295; H10D 30/43; H10D 30/6729; H10D 30/6735; H10D 30/6757; H10D 62/121; H10D 84/0149; H10D 84/038; H10D 84/83

(57) ABSTRACT

The present disclosure relates to an integrated circuit (IC) structure. The IC structure includes a semiconductor device having a frontside and a backside opposite the frontside. A first interconnect structure disposed on the frontside of the semiconductor device. The first interconnect structure comprises a first dielectric structure having a plurality of inter-level dielectric (ILD) layers. A second dielectric structure disposed on the backside of the semiconductor device. The second dielectric structure comprises a first high thermal conductivity layer having a thermal conductivity greater than that of the ILD layers.

### REFERENCE TO RELATED APPLICATION

This application claims the benefit of U.S. Provisional Application No. 63/589,715, filed on Oct. 12, 2023, the contents of which are hereby incorporated by reference in their entirety.

### BACKGROUND

Modern day integrated circuits (ICs) contain millions of semiconductor devices. The semiconductor devices are electrically interconnected by way of conductive interconnects that are formed above and/or below the semiconductor devices on an IC. The conductive interconnects are disposed within a dielectric structure and are configured to selectively provide power to the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated circuit (IC) structure comprising an interconnect structure having one or more high thermal conductivity layers disposed on a plurality of semiconductor devices.

FIGS. 2A-2B illustrate various cross-sectional views of some additional embodiments of an IC structure comprising an interconnect structure having one or more high thermal conductivity layers disposed on a plurality of semiconductor devices.

FIG. 3 illustrates an isometric view of some embodiments of a first semiconductor device of the IC structure of FIGS. 2A-2B.

FIGS. 4A-4B through 9A-9B illustrate various cross-sectional views of some other embodiments of an IC structure comprising an interconnect structure having one or more high thermal conductivity layers disposed on a plurality of semiconductor devices.

FIG. 10 illustrates a cross-sectional view of some other embodiments of an IC structure comprising an interconnect structure having one or more high thermal conductivity layers disposed on a plurality of semiconductor devices.

FIGS. 11 through 24A-24B illustrate various cross-sectional views of some embodiments of a method for forming an IC structure comprising an interconnect structure having one or more high thermal conductivity layers disposed on a plurality of semiconductor devices.

FIGS. 25A-25B through 27A-27B illustrate various cross-sectional views of some embodiments of a method for forming an interconnect structure having one or more high thermal conductivity layers on a plurality of semiconductor devices.

FIGS. 28 through 37A-37B illustrate various cross-sectional views of some other embodiments of a method for forming an IC structure comprising an interconnect structure having one or more high thermal conductivity layers disposed on a plurality of semiconductor devices.

FIGS. 38A-38B through 39A-39B illustrate various cross-sectional views of some other embodiments of a method for forming at least a portion of an interconnect structure having one or more high thermal conductivity layers on a plurality of semiconductor devices.

FIG. 40 illustrates a flow diagram of some embodiments of a method for forming an IC structure comprising an interconnect structure having one or more high thermal conductivity layers disposed on a plurality of semiconductor devices.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit (IC) structure may include a plurality of semiconductor devices (e.g., transistors) on a frontside of a device layer (e.g., a silicon substrate). A first interconnect structure is disposed on the frontside of the device layer. The first interconnect structure is bonded to a carrier substrate and a second interconnect structure is disposed on a backside of the device layer. The first and second interconnect structures facilitate electrically coupling the semiconductor devices together and/or to other devices. The second interconnect structure comprises a dielectric structure on the device layer and a plurality of conductive interconnects in the dielectric structure. During operation, the semiconductor devices and/or the plurality of conductive interconnects may generate heat (e.g., due to Joule heating). Dissipation of the heat generated during operation of the IC structure has become increasingly important as devices are scaled down and/or more densely packed together. The dielectric structure generally comprises a low dielectric constant material (e.g., silicon dioxide or the like) that increases electrical isolation between the conductive interconnects. However, the low dielectric constant material of the dielectric structure has low thermal conductivity (i.e., has a low ability to dissipate heat).

During formation of the IC structure the semiconductor devices are formed on the device layer and the first interconnect structure is formed on the semiconductor devices. A thinning process is performed on the device layer after bonding the first interconnect structure to the carrier substrate. This removes all of or a substantial portion of the device layer from over the semiconductor devices, where the device layer has a relatively high thermal conductivity (e.g., greater than 10 Watt per meter-Kelvin (W/m-K)). Subsequently, the second interconnect structure is formed on the backside of the device layer. A challenge with the IC structure is high localized heat accumulation across the IC structure. For example, the dielectric structure of the second interconnect structure contacts portions of the semiconductor devices and/or may be disposed relatively close to the semiconductor devices. The low dielectric constant material of the dielectric structure has a relatively low thermal conductivity (e.g., about 0.9 watts per meter-kelvin (W/m-K) or the like). The low thermal conductivity can cause high localized heat accumulation at or around the semiconductor devices. The high localized heat accumulation across the IC structure can cause breakdown of the semiconductor devices and/or delamination of layers in the IC structure. Accordingly, the IC structure has low thermal dissipation performance (e.g., has low dissipation of heat generated by the semiconductor devices) that can reduce a reliability and overall performance of the IC structure.

Various embodiments of the present application are directed towards an IC structure comprising a high thermal conductivity layer disposed on a plurality of semiconductor devices and configured to increase dispersion of heat away from the semiconductor devices. In some embodiments, the IC structure comprises a plurality of semiconductor devices disposed on a device layer and a first interconnect structure on a frontside of the device layer. The first interconnect structure is bonded to a carrier substrate and a second interconnect structure is disposed on a backside of the device layer. The second interconnect structure comprises a dielectric structure and a plurality of conductive interconnects disposed in the dielectric structure. The dielectric structure comprises one or more high thermal conductivity layers disposed on the plurality of semiconductor devices. The one or more high thermal conductivity layers each have a relatively high thermal conductivity (e.g., greater than about 10 W/m-K) and are configured to dissipate heat away from the semiconductor devices and/or the plurality of conductive interconnect structures. As a result, heat may be efficiently transferred away from regions of the IC structure that are prone to high localized heat accumulation (e.g., heat may be efficiently transferred away from the semiconductor devices). Thus, the one or more high thermal conductivity layers increases a thermal dissipation performance of the IC structure and decreases or eliminates high localized heat accumulation across the IC structure. This increases a reliability and overall performance of the IC structure.

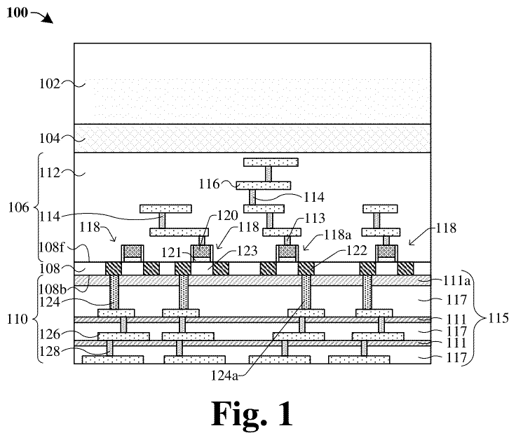

FIG. 1 illustrates a cross-sectional view of some embodiments of an integrated circuit (IC) structure 100 comprising an interconnect structure having one or more high thermal conductivity layers disposed on a plurality of semiconductor devices.

The IC structure 100 includes a first interconnect structure 106 disposed on a frontside 108f of a device layer 108. An insulating layer 104 is disposed on the first interconnect structure 106 and a carrier substrate 102 overlies the insulating layer 104. A plurality of semiconductor devices 118 are disposed within and/or on the device layer 108. The first interconnect structure 106 comprises a first dielectric structure 112 and a plurality of first conductive interconnects 113, 114, 116 disposed in the first dielectric structure 112. The plurality of first conductive interconnects 113, 114, 116 includes a plurality of first conductive contacts 113, a plurality of first conductive wires 116, and a plurality of first conductive vias 114. The plurality of first conductive interconnects 113, 114, 116 are electrically coupled to the semiconductor devices 118.

In some embodiments, the semiconductor devices 118 are configured as a transistor and comprise a gate dielectric 121 disposed over the device layer 108, a gate electrode 120 over the gate dielectric 121, one or more semiconductor channels 123, and a pair of source/drain structures 122 disposed on opposing sides of the one or more semiconductor channels 123. Source/drain region(s) may refer to a source or a drain, individually or collectively dependent upon the context. In various embodiments, the one or more semiconductor channels 123 are part of the device layer 108 and/or comprise a same material (e.g., silicon) as the device layer 108. In some embodiments, the pair of source/drain structures 122 may be doped regions of the device layer 108 or may be or comprise doped epitaxial silicon. The gate electrode 120 overlies the one or more semiconductor channels 123. In some embodiments, the gate electrode 120 overlies a top surface of the one or more semiconductor channels 123 and extends along sidewalls of the one or more semiconductor channels 123. In various embodiments, during use of the semiconductor devices 118, the gate electrode 120 of each semiconductor device 118 may be selectively biased to vary a conductivity of the one or more semiconductor channels 123 between the pair of source/drain structures 122. The semiconductor devices 118 may, for example, be planar metal-oxide-semiconductor (MOS) field-effect transistors (FETs), gate-all-around (GAA) FETs, fin FETs (FinFETs), nanowire FETs, nanoring FETs, nanosheet (NS) FETs (NSFETs), some other type of semiconductor device and/or transistor, or any combination of the foregoing.

The IC structure 100 further includes a second interconnect structure 110 disposed on a backside 108b of the device layer 108. The second interconnect structure 110 includes a second dielectric structure 115 and a plurality of second conductive interconnects 124, 126, 128 disposed in the second dielectric structure 115. The plurality of second conductive interconnects 124, 126, 128 includes a plurality of second conductive contacts 124, a plurality of second conductive wires 126, and a plurality of second conductive vias 128. The plurality of second conductive interconnects 124, 126, 128 are electrically coupled to the semiconductor devices 118 and/or the first interconnect structure 106. In various embodiments, one or more of the second conductive contacts 124 directly contact one or more structures of the semiconductor devices 118. For example, an individual second conductive contact 124a directly contacts a source/drain region 122 of an individual semiconductor device 118a in the plurality of semiconductor devices 118.

The second dielectric structure 115 comprises a plurality of high thermal conductivity layers 111 stacked with a plurality of dielectric layers 117. The plurality of high thermal conductivity layers 111 comprises a first high thermal conductivity layer 111a disposed along the backside 108b of the device layer 108. The plurality of dielectric layers 117 comprise a low dielectric constant material with a relatively low thermal conductivity (e.g., less than about 1 W/m-K). The high thermal conductivity layers 111 comprise a dielectric material having a relatively high thermal conductivity (e.g., greater than about 10 W/m-K) and are configured to efficiently transfer heat away from the plurality of semiconductor devices 118 and/or the plurality of second conductive interconnects 124, 126, 128. In various embodiments, the thermal conductivity of the high thermal conductivity layers 111 is greater than thermal conductivities of the first dielectric structure 112, the device layer 108, the insulating layer 104, and/or the plurality of dielectric layers 117.

During operation of the IC structure 100, current running through conductive structures of the first and/or second interconnect structures 106, 110 and/or through the semiconductor devices 118 causes a generation of heat. In various embodiments, this can result in heat accumulating at or around the semiconductor devices 118. By virtue of the second dielectric structure 115 comprising the high thermal conductivity layers 111, heat may be efficiently dissipated away from regions of the IC structure 100 that are prone to high localized heat accumulation (e.g., heat is efficiently transferred away from the semiconductor devices 118). The effective dissipation of heat increases a thermal dissipation performance of the IC structure 100 and decreases or eliminates high localized heat accumulation across the IC structure 100. As a result, a performance of the semiconductor devices 118 is increased and damage to the semiconductor devices 118 and/or the conductive structures of the first and/or second interconnect structures 106, 110 is decreased. Thus, a reliability and overall performance of the IC structure 100 are increased.

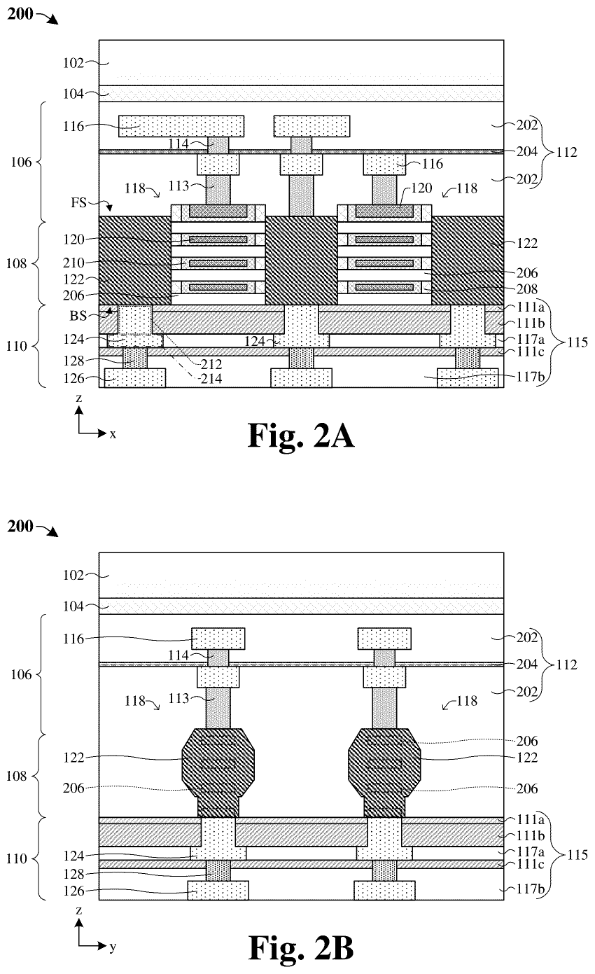

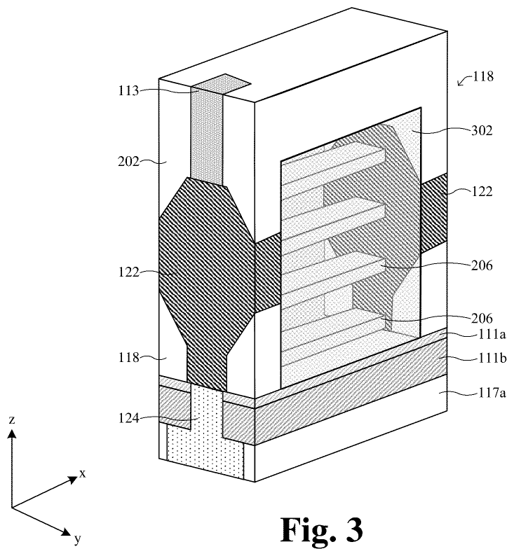

FIGS. 2A-2B illustrate various cross-sectional views of some embodiments of an IC structure 200 comprising an interconnect structure having one or more high thermal conductivity layers. FIG. 2A illustrates a cross-sectional view of some embodiments of the IC structure 200 taken along a first plane (e.g., the z-x plane). FIG. 2B illustrates a cross-sectional view of some embodiments of the IC structure 200 taken along a second plane (e.g., the z-y plane) perpendicular to the first plane.

As illustrated in FIG. 2A, the IC structure 200 includes a first interconnect structure 106 on a frontside FS of a plurality of semiconductor devices 118 and a second interconnect structure 110 on a backside BS of the plurality of semiconductor devices 118. The frontside FS of the semiconductor devices 118 corresponds to an upper surface of the semiconductor devices 118 and faces the first interconnect structure 106. The backside BS of the semiconductor devices 118 corresponds to a lower surface of the semiconductor devices 118 and faces the second interconnect structure 110. The frontside FS is opposite the backside BS. In various embodiments, the semiconductor devices 118 are disposed within and/or on a device layer 108, where the frontside FS corresponds to a first surface of the device layer 108 and the backside BS corresponds to a second surface of the device layer 108 opposite the second surface.

An insulating layer 104 is disposed on the first interconnect structure 106 and a carrier substrate 102 overlies the insulating layer 104. The insulating layer 104 may, for example, be or comprise an oxide such as silicon dioxide or some other suitable material. The carrier substrate 102 is a semiconductor substrate or some other suitable substrate. In some embodiments, the carrier substrate 102 is or comprises silicon, germanium, some other suitable material, or any combination of the foregoing. In various embodiments, the insulating layer 104 is configured to facilitate bonding between the carrier substrate 102 and the first interconnect structure 106.

The semiconductor devices 118 are gate-all-around (GAA) field-effect transistors (FETs). In other embodiments, the semiconductor devices 118 may alternatively be planar metal-oxide-semiconductor (MOS) FETs (MOSFETs), fin FETs (FinFETs), nanowire FETs, nanoring FETs, nanosheet (NS) FETs (NSFETs), some other type of semiconductor device and/or transistor, or any combination of the foregoing. The semiconductor devices 118 respectively comprise a plurality of semiconductor channels 206, a gate dielectric structure 210, a gate electrode 120, a spacer layer 208, and corresponding source/drain regions 122. The semiconductor channels 206 for each of the semiconductor devices 118 are vertically stacked with one another. The gate electrode 120 overlies the semiconductor channels 206 and is spaced vertically between adjacent semiconductor channels 206. The gate dielectric structure 210 is spaced between the gate electrode 120 and the semiconductor channels 206. In various embodiments, the gate dielectric structure 210 and the gate electrode 120 both continuously extend around bottom and top surfaces of at least two or more of the semiconductor channels 206. A gate structure of the semiconductor devices 118 includes the gate electrode 120 and the gate dielectric structure 210.

In various embodiments, the semiconductor channels 206 are part of and/or are formed from the device layer 108 and comprise a semiconductor material (e.g., silicon) of the device layer 108. In some embodiments, the semiconductor channels 206 are nanostructures, nanosheets, some other suitable structure, or the like. The semiconductor channels 206 continuously extend between two of the source/drain regions 122. In various embodiments, the source/drain regions 122 directly contact corresponding semiconductor channels 206. The spacer layer 208 is disposed between the source/drain regions 122 and the gate dielectric structure 210. In various embodiments, two of the semiconductor devices 118 in the plurality of semiconductor devices 118 share one of the source/drain regions 122. In alternative embodiments, the semiconductor devices 118 do not share a source/drain region 122 and instead each have a discrete pair of source/drain regions and are laterally separated from one another by a non-zero distance (not shown). By applying suitable bias conditions to the gate electrode 120 and the source/drain regions 122, a conductivity of the semiconductor channels 206 by be controlled (e.g., may be switched between one or more conducting states and a non-conducting state).

In some embodiments, the gate electrode 120 may, for example, be or comprise polysilicon, titanium, aluminum, tungsten, titanium, tantalum, gallium, carbon, some other suitable material, or any combination of the foregoing. In various embodiments, the gate dielectric structure 210 may, for example, be or comprise silicon dioxide, aluminum oxide, hafnium oxide, silicon oxynitride, a high-k dielectric material, some other suitable dielectric, or any combination of the foregoing. In further embodiments, the source/drain regions 122 may, for example, be or comprise silicon, germanium, silicon germanium, an epitaxial semiconductor material (e.g., epitaxial silicon, epitaxial germanium, epitaxial silicon germanium, etc.), some other suitable material, or any combination of the foregoing. Further, the source/drain regions 122 are doped. In some embodiments, the source/drain regions 122 comprise silicon or epitaxial silicon doped with phosphorus, where a doping concentration of phosphorus in the source/drain regions 122 is about 1*10²¹ atoms/cm³ or greater. In yet further embodiments, the source/drain regions 122 comprise epitaxial silicon germanium doped with boron, where a doping concentration of boron in the source/drain regions 122 is about 5*10²⁰ atoms/cm³ or greater. In yet further embodiments, the spacer layer 208 may, for example, be or comprise silicon oxynitride, silicon oxycarbide, silicon oxycarbonitride, some other dielectric material, or any combination of the foregoing. In various embodiments, the spacer layer 208 comprises silicon oxycarbonitride, where an atomic percentage of carbon in the spacer layer 208 is about 6 percent or less.

The first interconnect structure 106 is electrically coupled to the plurality of semiconductor devices 118 on the frontside FS of the semiconductor devices 118. The first interconnect structure 106 comprises a first dielectric structure 112 and a plurality of first conductive interconnects 113, 114, 116 that includes a plurality of first conductive contacts 113, a plurality of first conductive wires 116, and a plurality of first conductive vias 114. A topmost layer of the plurality of first conductive wires 116 is separated from the insulating layer 104 by at least a portion of the first dielectric structure 112. In further embodiments, the topmost layer of the plurality of first conductive wires 116 directly contacts at least a portion of a bottom surface of the insulating layer 104. In various embodiments, the first dielectric structure 112 comprises a plurality of inter-level dielectric (ILD) layers 202 and one or more etch stop layers 204 disposed between corresponding ILD layers 202. The plurality of ILD layers 202 may, for example, be or comprise an oxide (e.g., silicon dioxide), borosilicate glass, silicon oxycarbide, silicon oxycarbonitride, a low-k dielectric material, or the like. The one or more etch stop layers 204 may, for example, be or comprise silicon nitride, silicon carbon nitride, some other dielectric material, or the like. In some embodiments, a thermal conductivity of the one or more ILD layers 202 is relatively low (e.g., less than about 1 W/m-K).

The second interconnect structure 110 is electrically coupled to the plurality of semiconductor devices 118 on the backside BS of the semiconductor devices 118. The second interconnect structure 110 includes a second dielectric structure 115 and a plurality of second conductive interconnects 124, 126, 128 disposed in the second dielectric structure 115. The plurality of second conductive interconnects 124, 126, 128 includes a plurality of second conductive contacts 124, a plurality of second conductive wires 126, and a plurality of second conductive vias 128. In various embodiments, the second conductive contacts 124 directly contact a source/drain region 122 of a corresponding semiconductor device 118. The plurality of second conductive interconnects 124, 126, 128 may, for example, be or comprise titanium nitride, aluminum, tungsten, copper, ruthenium, molybdenum, titanium aluminum, tantalum nitride, some other conductive material, or any combination of the foregoing.

The second dielectric structure 115 comprises a plurality of high thermal conductivity layers 111a-c and a plurality of dielectric layers 117a-b. The plurality of dielectric layers 117a-b includes a first dielectric layer 117a and a second dielectric layer 117b. The plurality of high thermal conductivity layers 111a-c are configured to increase a transfer of heat within the second dielectric structure 115 along a horizontal direction. The plurality of high thermal conductivity layers 111a-c include a first high thermal conductivity layer 111a disposed along the backside BS of the plurality of semiconductor devices 118 and a second high thermal conductivity layer 111b disposed on the first high thermal conductivity layer 111a. In some embodiments, the plurality of second conductive contacts 124 respectively comprise a vertical segment 212 and a body segment 214. In various embodiments, the vertical segment 212 may be configured as a contact or via and the body segment 214 may be configured as a wire. In some embodiments, the vertical segment 212 is disposed in the first and second high thermal conductivity layers 111a-b and the body segment 214 is disposed in the first dielectric layer 117a. In further embodiments, a third high thermal conductivity layer 111c of the plurality of high thermal conductivity layers 111a-c continuously extends along bottom surfaces of the second conductive contacts 124. The first and second high thermal conductivity layers 111a-b directly contact opposing sidewalls of the vertical segment 212 and/or directly contact a top surface of the body segment 214. Further, the third high thermal conductivity layer 111c directly contacts opposing sidewalls of the second conductive vias 128. In various embodiments, the second conductive contacts 124 may be configured as a conductive plug. In further embodiments, the second conductive contacts 124 are configured as or directly electrically coupled to a power rail, where the second conductive contacts 124 may deliver high power to the semiconductor devices 118.

In some embodiments, the plurality of high thermal conductivity layers 111a-c comprise a material having a thermal conductivity greater than about 10 W/m-K, within a range of about 10 to 2,500 W/m-K, or some other suitable value. In some embodiments, the plurality of high thermal conductivity layers 111a-c may, for example, be or comprise aluminum nitride (AlN), boron nitride (BN), yttrium oxide (Y₂O₃), yttrium aluminum garnet (Y₃Al₅O₁₂), aluminum oxide (Al₂O₃), beryllium oxide (BeO), silicon carbide (SiC), graphene, diamond like carbon (DLC), diamond (e.g., near isotropic diamond grains), another suitable material, or any combination of the foregoing. In some embodiments, the plurality of high thermal conductivity layers 111a-c may be poly-crystalline, single crystalline, amorphous, or the like. For example, the high thermal conductivity layers 111a-c may be or comprise poly-crystal silicon carbide, single-crystal silicon carbide, or amorphous silicon carbide. In yet further embodiments, the high thermal conductivity layers 111a-c have a cubic crystal structure, a hexagonal crystal structure, a tetragonal crystal structure, an orthorhombic crystal structure, a monoclinic crystal structure, a triclinic crystal structure, or the like. In various embodiments, the high thermal conductivity layers 111a-c have a cubic crystal structure that may be different from a crystal structure of the dielectric layers 117a-b, the ILD layers 202, and/or the one or more etch stop layers 204. For example, the dielectric layers 117a-b and/or the ILD layers 202 may comprise silicon dioxide having a hexagonal crystal structure and the one or more etch stop layers 204 may comprise silicon nitride having a hexagonal crystal structure, where the high thermal conductivity layers 111a-c have a cubic crystal structure. The high thermal conductivity layers 111a-c having the cubic crystal structure increases an ability for the high thermal conductivity layers 111a-c to dissipate heat. In further embodiments, the high thermal conductivity layers 111a-c have a higher thermal conductivity than that of the plurality of semiconductor channels 206, the source/drain regions 122, and/or the gate dielectric structure 210.

In yet further embodiments, the high thermal conductivity layers 111a-c are further configured to operate as an etch stop layer for the second interconnect structure 110, where the high thermal conductivity layers 111a-c comprise a material that is more resistant to etching than the plurality of dielectric layers 117a-b. For example, the high thermal conductivity layers 111a-c are etched at a first rate that is less than a second rate that the plurality of dielectric layers 117a-b are etched when exposed to an etchant (e.g., such as a dry etchant comprising fluorine). In some embodiments, a top surface of the first high thermal conductivity layer 111a is aligned with a top surface of the plurality of second conductive contacts 124. In various embodiments, a thickness of the first high thermal conductivity layer 111a is less than a thickness of the second high thermal conductivity layer 111b. Further, the thickness of the second high thermal conductivity layer 111b is greater than a thickness of the first dielectric layer 117a. In some embodiments, thicknesses of the high thermal conductivity layers 111a-c are each greater than a thickness of the one or more etch stop layers 204. The high thermal conductivity layers 111a-c comprise a material different from that of the one or more etch stop layers 204. In various embodiments, the high thermal conductivity layers 111a-c may be or comprise different materials from one another. In yet further embodiments, the high thermal conductivity layers 111a-c may each be or comprise a same material.

By virtue of the high thermal conductivity layers 111a-c being disposed in the second interconnect structure 110 and along the backside BS of the semiconductor devices 118, heat may be efficiently dissipated away from the semiconductor devices 118 and/or conductive interconnects of the second interconnect structure 110. As a result, a performance and reliability of the IC structure 200 is increased.

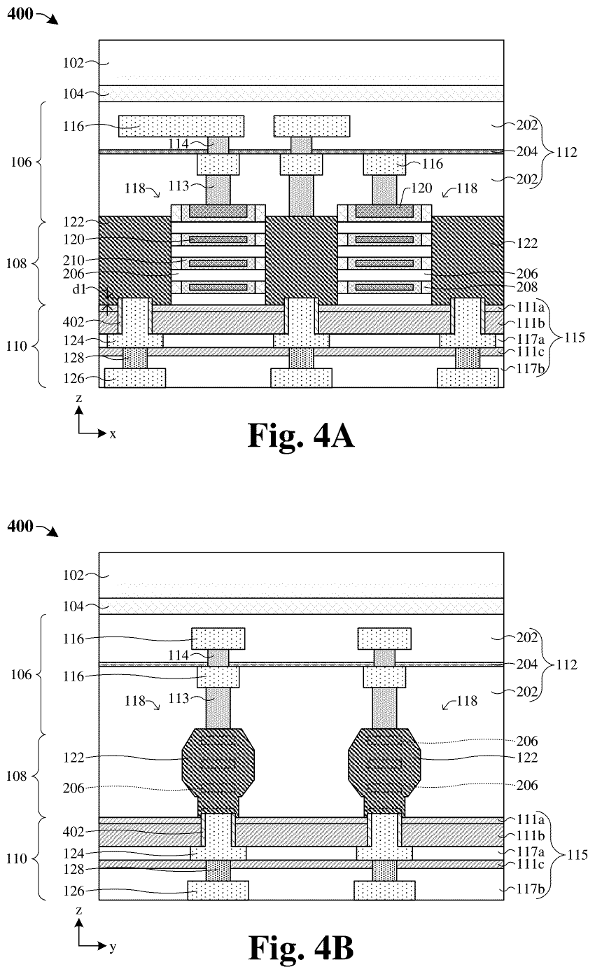

It will be appreciated that the high thermal conductivity layers 111a-c may be disposed at different locations within the IC structure 200, and the IC structure 200 may have a different number of high thermal conductivity layers disposed in the second interconnect structure 110. FIGS. 4A-4B through 10 illustrate various cross-sectional views of the high thermal conductivity layers being disposed at different locations within the second interconnect structure 110 and/or the second interconnect structure 110 having different numbers of high thermal conductivity layers.

As illustrated in FIG. 2B, the plurality of semiconductor devices 118 are disposed in an array comprising at least two rows and at least two columns. For instance, the cross-sectional view of FIG. 2A is taken along a first column of the plurality of semiconductor devices 118 and the cross-sectional view of FIG. 2B is taken along the source/drain regions 122 of a first row of the plurality of semiconductor devices 118. In some embodiments, the first dielectric structure 112 extends along a top surface of the source/drain regions 122 to the second dielectric structure 115. In various embodiments, a bottom surface of the first dielectric structure 112 directly contacts a top surface of the second dielectric structure 115.

FIG. 3 illustrates an isometric view of some embodiments of an individual semiconductor device 118 of the IC structure 200 of FIGS. 2A-2B.

As illustrated in FIG. 3, the semiconductor device 118 comprises a gate structure 302 disposed over and around the plurality of semiconductor channels 206. In various embodiments, the gate structure 302 comprises the gate electrode (120 of FIGS. 2A-2B) and the gate dielectric structure (210 of FIGS. 2A-2B). The plurality of semiconductor channels 206 continuously laterally extend between the source/drain regions 122. In various embodiments, a vertical segment of an individual second conductive contact 124 is disposed in the first and second high thermal conductivity layers 111a-b. In some embodiments, the first high thermal conductivity layer 111a continuously extends long bottom surfaces of the source/drain regions 122.

FIGS. 4A-4B through 9A-9B illustrate various cross-sectional views of some other embodiments of the IC structure 200 of FIGS. 2A-2B. Figures with a suffix of “A” illustrate a cross-sectional view taken along the z-x plane and figures with a suffix of “B” illustrate a cross-sectional view taken along the z-y plane.

FIGS. 4A-4B illustrate various cross-sectional views of some embodiments of an IC structure 400, in which the second conductive contacts 124 extend above a bottom surface of the source/drain regions 122 by a non-zero distance d1. In various embodiments, a liner layer 402 is disposed along opposing sidewalls of each of the second conductive contacts 124. The liner layer 402 may, for example, be or comprise silicon nitride, silicon carbide, some other suitable material, or any combination of the foregoing. In yet further embodiments, the liner layer 402 is omitted (not shown) and the source/drain regions 122 directly contact opposing sidewalls of a corresponding second conductive contact 124.

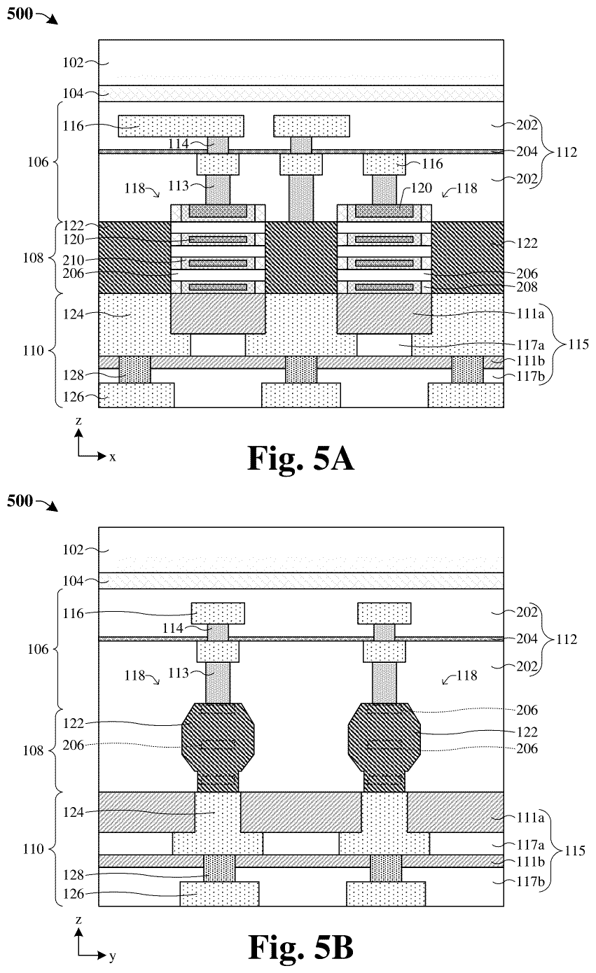

FIGS. 5A-5B illustrate various cross-sectional views of some embodiments of an IC structure 500, in which a width of each second conductive contact 124 is greater than a width of a corresponding source/drain region 122. In various embodiments, each second conductive contact 124 continuously extends along an entire bottom surface of a corresponding source/drain region 122.

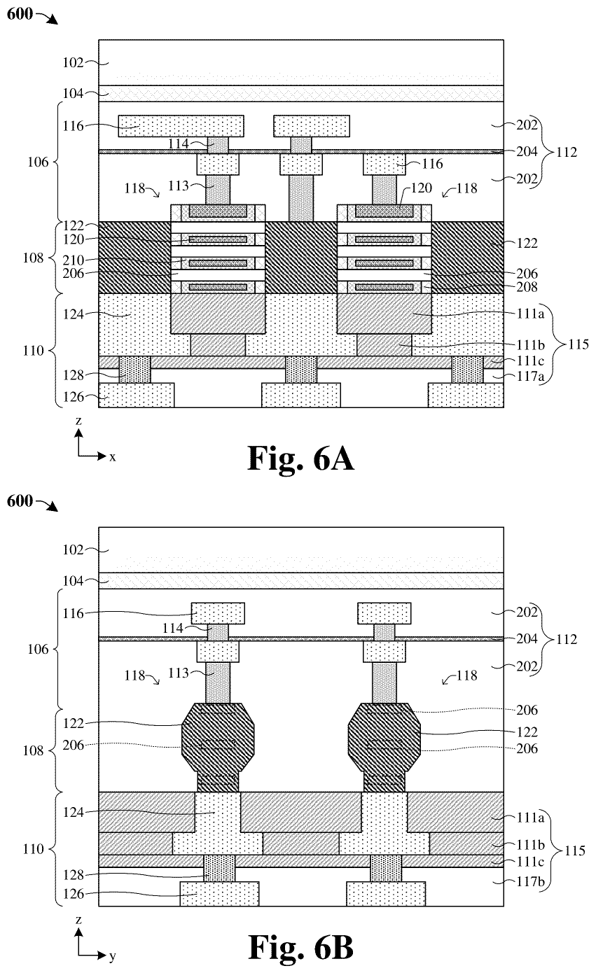

FIGS. 6A-6B illustrate various cross-sectional views of some embodiments of an IC structure 600, in which the plurality of second conductive contacts 124 are disposed in the first high thermal conductivity layer 111a and the second high thermal conductivity layer 111b. Further, the second high thermal conductivity layer 111b continuously extends along a top surface of the third high thermal conductivity layer 111c. As a result, an ability for the IC structure 600 to dissipate heat away from the second conductive contacts 124 and/or the semiconductor devices 118 is increased, thereby increasing an overall performance of the IC structure 600.

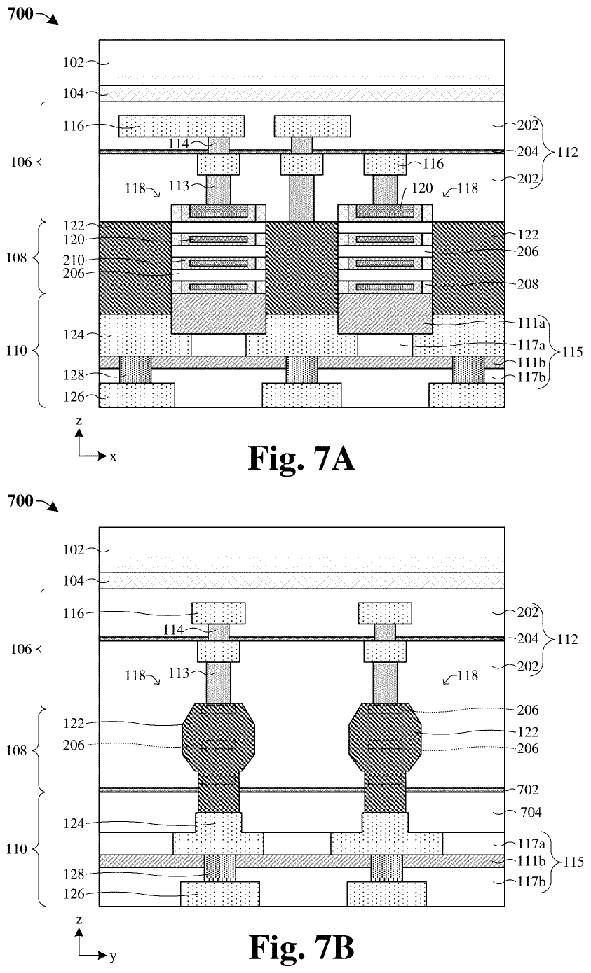

FIGS. 7A-7B illustrate various cross-sectional views of some embodiments of an IC structure 700 corresponding to some other embodiments of the IC structure 500 of FIGS. 5A-5B, in which the source/drain regions 122 extend below a top surface of the first high thermal conductivity layer 111a.

Further, in some embodiments as shown in FIG. 7B a lower etch stop layer 702 is disposed along a bottom surface of the first dielectric structure 112 and an isolation structure 704 is disposed along a lower portion of the source/drain regions 122 and an upper portion of the second conductive contacts 124. The lower etch stop layer 702 may, for example, be or comprise silicon nitride, silicon oxynitride, some other suitable dielectric, or any combination of the foregoing. In various embodiments, the lower etch stop layer 702 has a thermal conductivity less than that of the high thermal conductivity layers 111a-b. In various embodiments, the first dielectric layer 117a extends from a bottom surface of the first high thermal conductivity layer 111a to opposing sidewalls of the first high thermal conductivity layer 111a. In some embodiments, the isolation structure 704 may be configured as a shallow trench isolation (STI) structure. The isolation structure 704 may, for example, be or comprise silicon dioxide, silicon nitride, some other dielectric material, or any combination of the foregoing. In yet further embodiments, the isolation structure 704 has a thermal conductivity less than that of the high thermal conductivity layers 111a-b.

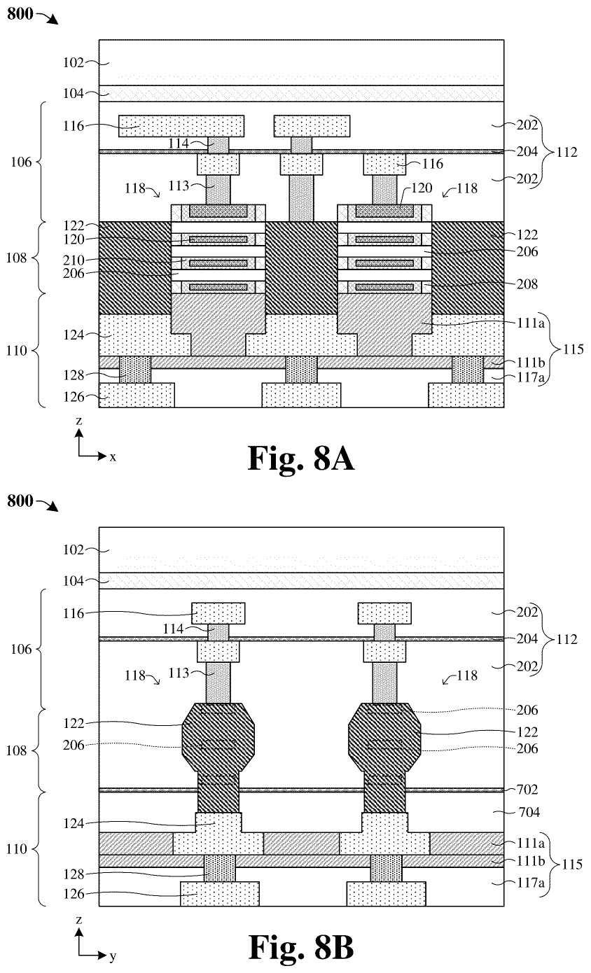

FIGS. 8A-8B illustrate various cross-sectional views of some embodiments of an IC structure 800 corresponding to some other embodiments of the IC structure 700 of FIGS. 7A-7B, in which the first high thermal conductivity layer 111a continuously extends from the source/drain regions 122 to a point aligned with a bottom surface of the second conductive contacts 124. As shown in FIG. 8B, in some embodiments, the isolation structure 704 extends from sidewalls of the source/drain regions 122 to sidewalls of the second conductive contacts 124.

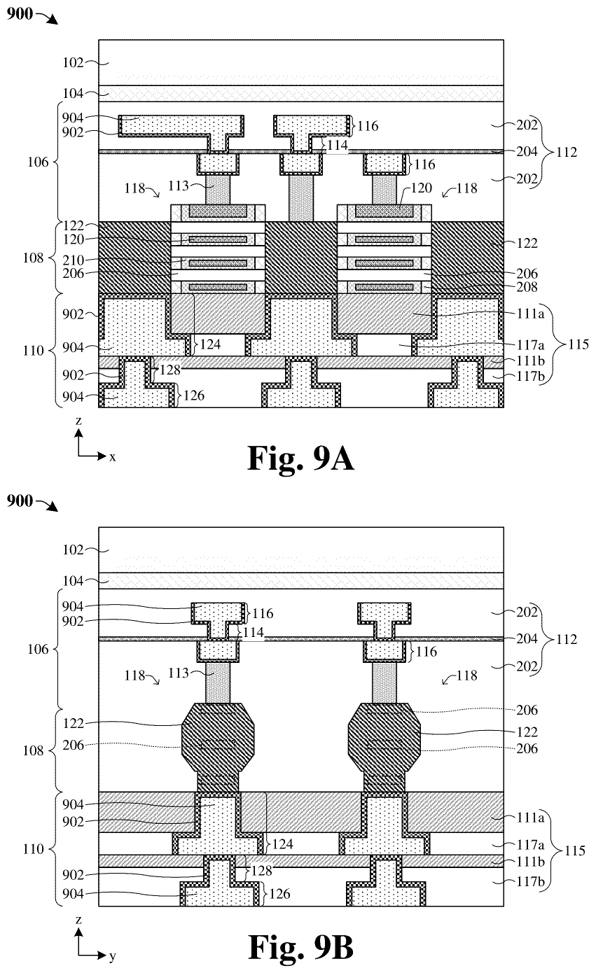

FIGS. 9A-9B illustrate various cross-sectional views of some embodiments of an IC structure 900 corresponding to some other embodiments of the IC structure 500 of FIGS. 5A-5B, in which conductive interconnects of the first and second interconnect structures 106, 110 respectively comprise a conductive core structure 904 surrounded by a conductive liner layer 902. In some embodiments, the conductive core structure 904 may, for example, be or comprise tungsten, aluminum, copper, ruthenium, tantalum, titanium, some other conductive material, or any combination of the foregoing. In various embodiments, the conductive liner layer 902 may, for example, be or comprise titanium nitride, tantalum nitride, some other suitable material, or any combination of the foregoing. In some embodiments, the conductive liner layer 902 is configured as a barrier layer and is disposed between the conductive core structure 904 and corresponding dielectric layer(s) of the first or second dielectric structures 112, 115.

In various embodiments, an upper surface of the conductive liner layer 902 of each of the second conductive contacts 124 is disposed along a bottom surface of the first high thermal conductivity layer 111a. In yet further embodiments, the top surface of the conductive liner layer 902 of each of the second conductive contacts 124 is disposed along a corresponding source/drain region 122 and is aligned with a top surface of the first high thermal conductivity layer 111a.

It will be appreciated that while the IC structure 900 illustrates another embodiment of the IC structure 500 of FIGS. 5A-5B, any one of the IC structures of FIGS. 1, 2A-2B, 3, 4A-4B, and 6A-B through 8A-8B may comprise the conductive liner layer 902 and the conductive core structure 904 as illustrated and/or described in FIGS. 9A-9B. Further, it will be appreciated that while a single via level and a single wire level are shown in the second interconnect structure 110 of FIGS. 4A-4B through 9A-9B, more via levels and/or wire levels are amenable.

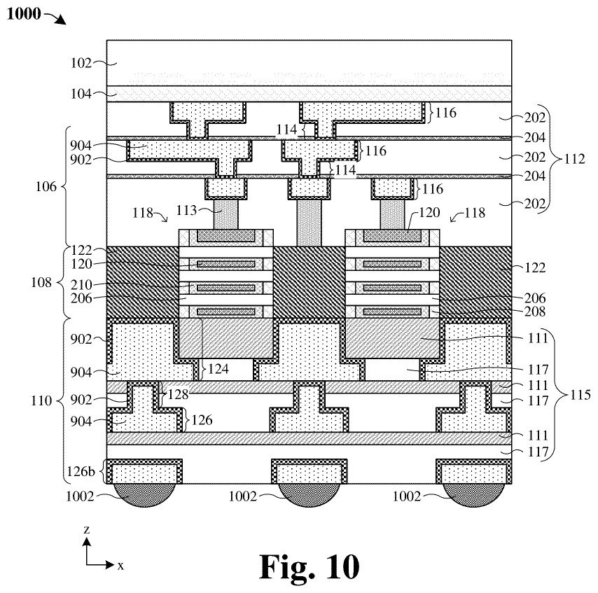

FIG. 10 illustrates a cross-sectional view of some other embodiments of an IC structure 1000 comprising an interconnect structure having one or more high thermal conductivity layers.

The IC structure 1000 comprises the first interconnect structure 106 disposed on an upper surface the plurality of semiconductor devices 118 and the second interconnect structure 110 disposed on a lower surface of the plurality of semiconductor devices 118. A bottommost layer 126b of the plurality of second conductive wires 126 of the second interconnect structure 110 may, for example, be configured as redistribution wires, bond pads, or the like. A plurality of solder bumps 1002 are disposed on the bottommost layer 126b of the plurality of second conductive wires 126 and are configured to couple and/or bond the IC structure 1000 to another semiconductor structure (e.g., to a package substrate, a semiconductor die, or the like).

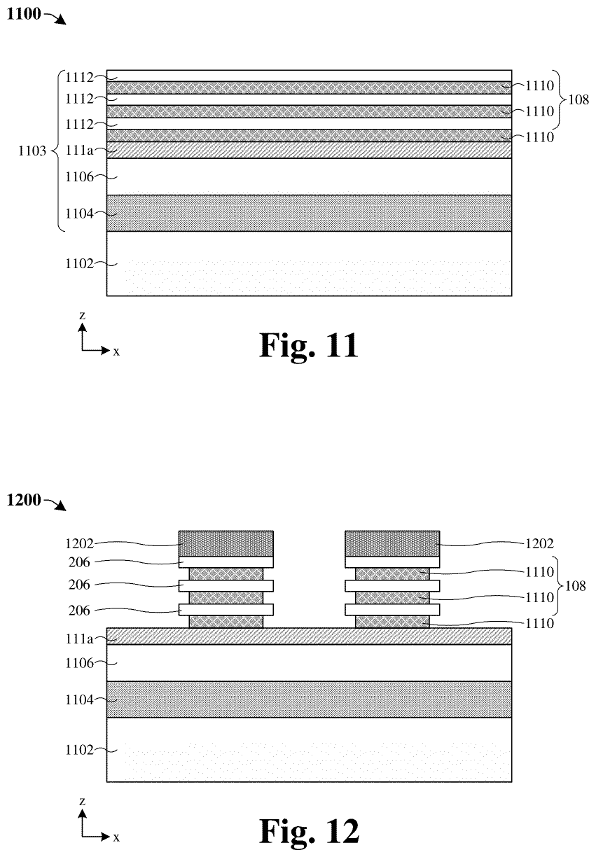

FIGS. 11 through 24A-24B illustrate various cross-sectional views of some embodiments of a method for forming an IC structure comprising an interconnect structure having one or more high thermal conductivity layers. Although FIGS. 11 through 24A-24B are described in relation to a method, it will be appreciated that the structures disclosed in the method are not limited to the method, but instead may stand alone as structures independent of the method. Further, although FIGS. 11 through 24A-24B are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part. In addition, figures with a suffix of “A” illustrate a cross-sectional view taken along the z-x plane and figures with a suffix of “B” illustrate a cross-sectional view taken along the z-y plane.

As shown in cross-sectional view 1100 of FIG. 11, a base substrate 1102 is provided and a stack of layers 1103 is formed over the base substrate 1102. The base substrate 1102 may, for example, be or comprise silicon, germanium, silicon germanium, some other semiconductor body, or the like. In some embodiments, the stack of layers 1103 includes an etch stop layer 1104 on the base substrate 1102, a lower semiconductor layer 1106 on the etch stop layer 1104, a first high thermal conductivity layer 111a, a plurality of first semiconductor layers 1110, and a plurality of second semiconductor layers 1112. The plurality of first semiconductor layers 1110 and the plurality of second semiconductors layers 1112 are alternatingly stacked with one another. In various embodiments, the plurality of second semiconductor layers 1112 are part of or define a device layer 108.

In some embodiments, a process for forming the etch stop layer 1104 includes depositing or growing the etch stop layer 1104 over the base substrate 1102 by, for example, a chemical vapor deposition (CVD) process, an epitaxial process, or some other suitable deposition or growth process. The lower semiconductor layer 1106 may be formed over the etch stop layer 1104 by, for example, a CVD process, an epitaxial process, or some other suitable deposition or growth process. The first high thermal conductivity layer 111a may be formed over the lower semiconductor layer 1106 by, for example, a CVD process, a thermal CVD process, a hybrid physical-CVD (HPCVD) process, a plasma-enhanced CVD (PECVD) process, a microwave-plasma CVD (MWCVD) process, a physical vapor deposition (PVD) process, a thermal atomic layer deposition (ALD) process, a plasma-enhanced ALD (PEALD) process, or some other suitable deposition or growth process. Further, the first semiconductor layers 1110 and the second semiconductor layers 1112 are each formed over the first high thermal conductivity layer 111a by an epitaxial process or some other suitable deposition or growth process. In various embodiments, the individual epitaxial process to form any one of the etch stop layer 1104, the lower semiconductor layer 1106, the first semiconductor layers 1110, and the second semiconductor layers 1112 may, for example, be or comprise molecular beam epitaxy (MBE), vapor phase epitaxy (VPE), liquid phase epitaxy (LPE), some other suitable epitaxial process, or any combination of the foregoing.

In various embodiments, the first high thermal conductivity layer 111a is deposited at a low processing temperature that is, for example, less than about 400 degrees Celsius, within a range of about 100 to 400 degrees Celsius, or some other suitable temperature. The first high thermal conductivity layer 111a may, for example, be or comprise aluminum nitride, boron nitride, yttrium oxide, yttrium aluminum garnet, aluminum oxide, beryllium oxide, silicon carbide, graphene, diamond like carbon, diamond, another suitable material, or any combination of the foregoing. The etch stop layer 1104 and/or the first semiconductor layers 1110 may, for example, be or comprise silicon germanium (e.g., having an atomic percentage of germanium within a range of about 10% to 35%), silicon, doped silicon (e.g., silicon doped with boron), or the like. The second semiconductor layers 1112 and/or the lower semiconductor layer 1106 may, for example, be or comprise silicon, epitaxial silicon, or some other suitable semiconductor material.

As shown in cross-sectional view 1200 of FIG. 12, a masking layer 1202 is formed over the plurality of second semiconductor layers (1112 of FIG. 11). Further, a patterning process is performed on the plurality of first semiconductor layers 1110 and the plurality of second semiconductor layers (1112 of FIG. 11) according to the masking layer 1202, thereby forming a plurality of semiconductor channels 206 vertically stacked with the first semiconductor layers 1110. In some embodiments, the patterning process includes performing a dry etch process, a wet etch process, another suitable etch process, or any combination of the foregoing. Further, the masking layer 1202 may be removed during or after the patterning process (not shown).

As shown in cross-sectional view 1300 of FIG. 13, a plurality of semiconductor devices 118 are formed over the base substrate 1102. In various embodiments, the semiconductor devices 118 are GAA FETs. The semiconductor devices 118 respectively comprise the plurality of semiconductor channels 206, a gate dielectric structure 210, a gate electrode 120, a spacer layer 208, and source/drain regions 122. The semiconductor channels 206 for each of the semiconductor devices 118 are vertically stacked with one another. The gate electrode 120 overlies the semiconductor channels 206 and is spaced vertically between adjacent semiconductor channels 206. The gate dielectric structure 210 is spaced between the gate electrode 120 and the semiconductor channels 206. The gate electrode 120 and the gate dielectric structure 210 of each semiconductor device 118 defines a gate structure of the corresponding semiconductor device.

In some embodiments, a process for forming the semiconductor devices 118 includes forming (e.g., by CVD, PVD, etc.) a dummy gate structure (not shown) over the first semiconductor layers (1110 of FIG. 12); forming (e.g., by CVD, PVD, ALD, etc.) the spacer layer 208 along the first semiconductor layers (1110 of FIG. 12) and the dummy gate structure; forming (e.g., by an epitaxial process) the source/drain regions 122 adjacent to the semiconductor channels; selectively removing the dummy gate structure and the first semiconductor layers (1110 of FIG. 12); forming (e.g., by CVD, PVD, etc.) the gate dielectric structure 210 on the semiconductor channels 206; and forming (e.g., by CVD, PVD, electroplating, electroless plating, etc.) the gate electrode 120 on the gate dielectric structure 210.

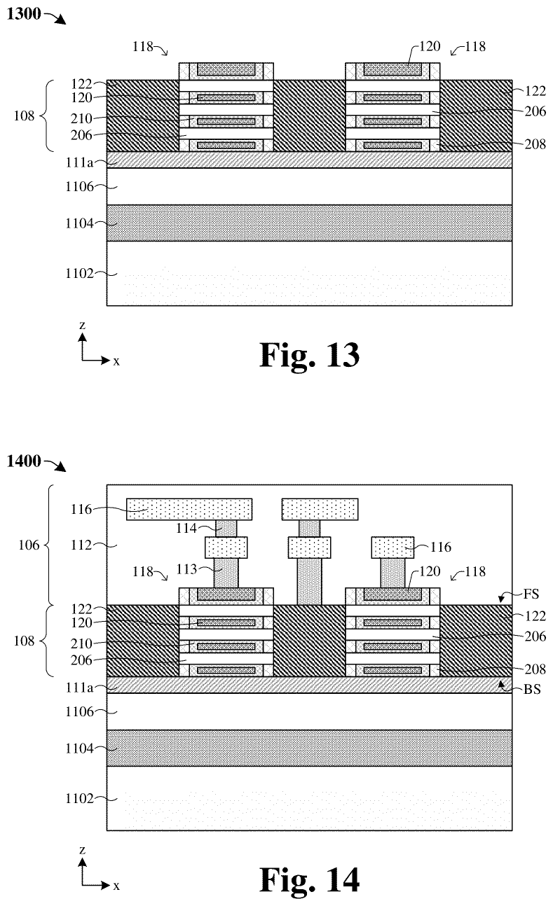

As shown in cross-sectional view 1400 of FIG. 14, a first interconnect structure 106 is formed over a frontside FS of the semiconductor devices 118. The first interconnect structure 106 comprises a plurality of first conductive contacts 113, a plurality of first conductive wires 116, and a plurality of first conductive vias 114 disposed within a first dielectric structure 112. In some embodiments, conductive structures of the first interconnect structure 106 may each be formed by a damascene process (e.g., a single damascene process or a dual damascene process) or some other suitable process. In further embodiments, the first dielectric structure 112 comprises one or more inter-level dielectric (ILD) layers and one or more etch stop layers (e.g., as illustrated and/or described in FIGS. 2A-2B) that may, for example, each be formed by CVD, PVD, ALD, or some other suitable growth or deposition process.

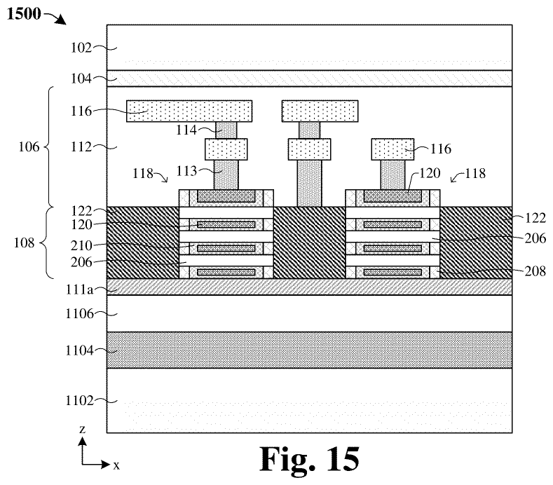

As shown in cross-sectional view 1500 of FIG. 15, a carrier substrate 102 is provided and subsequently bonded to the first interconnect structure 106. The carrier substrate 102 may, for example, be or comprise silicon, germanium, or some other suitable semiconductor substrate material. In various embodiments, bonding the carrier substrate 102 to the first interconnect structure 106 includes: forming (e.g., by CVD, PVD, ALD, etc.) an insulating layer 104 on the carrier substrate 102 and bonding (e.g., by fusion bonding, vacuum bonding, direct bonding, etc.) the insulating layer 104 to the first interconnect structure 106. The insulating layer 104 may, for example, be or comprise an oxide such as silicon dioxide or some other suitable material.

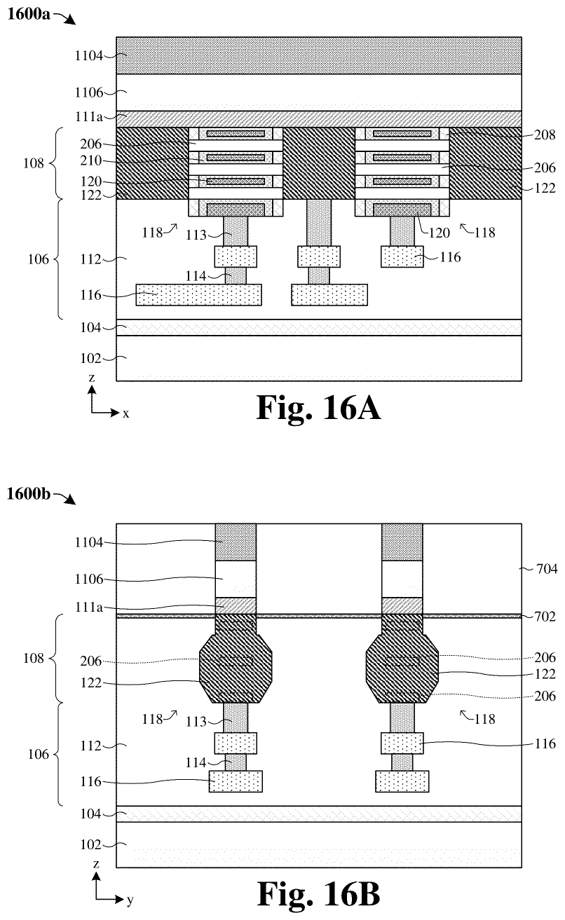

As shown in cross-sectional views 1600a and 1600b of FIGS. 16A-16B, the structure of FIG. 15 is flipped and a thinning process is performed to remove the base substrate (1102 of FIG. 15) from over the etch stop layer 1104. In various embodiments, the thinning process includes performing a mechanical grinding process, a chemical-mechanical polishing (CMP) process, an etching process, or some other suitable process into the base substrate (1102 of FIG. 15) until the etch stop layer 1104 is reached.

Further, as shown in in FIG. 16B, in some embodiments, an isolation structure 704 is disposed along sidewalls of the first high thermal conductivity layer 111a, sidewalls of the lower semiconductor layer 1106, and sidewalls of the etch stop layer 1104. In various embodiments, the isolation structure 704 is formed (e.g., by CVD, PVD, etc.) after the patterning process of FIG. 12. In various embodiments, the isolation structure 704 is configured as an STI structure or some other suitable isolation structure. Further, a lower etch stop layer 702 is disposed along the first dielectric structure 112. In some embodiments, the lower etch stop layer 702 is formed (e.g., by CVD, PVD, etc.) after forming the semiconductor devices 118 and before forming the first interconnect structure 106.

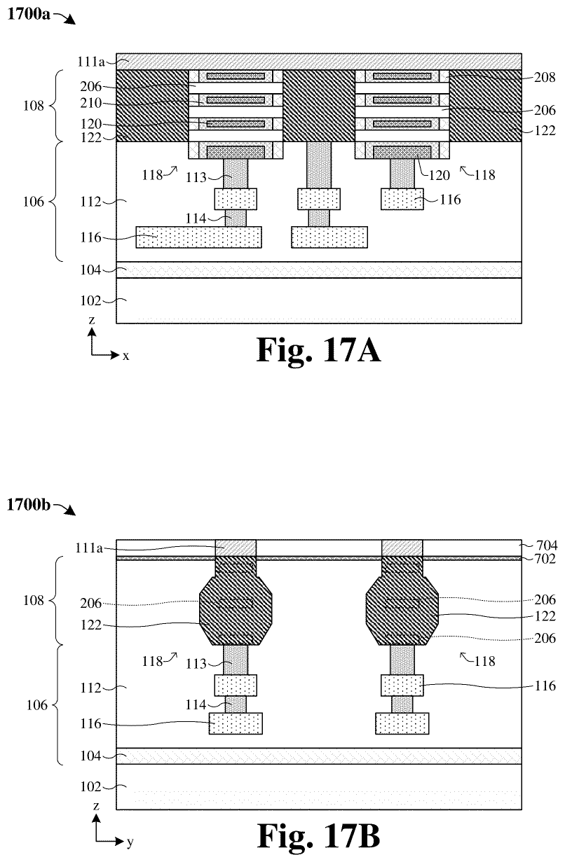

As shown in cross-sectional views 1700a and 1700b of FIGS. 17A-17B, a removal process is performed to remove the etch stop layer (1104 of FIGS. 16A-16B) and the lower semiconductor layer (1106 of FIGS. 16A-16B). In some embodiments, the removal process includes depositing (e.g., by CVD, PVD, etc.) a sacrificial oxide (e.g., silicon dioxide) over the etch stop layer (1104 of FIGS. 16A-16B) (not shown) and performing a planarization process (e.g., a CMP process) into the sacrificial oxide, the etch stop layer (1104 of FIGS. 16A-16B), and the lower semiconductor layer (1106 of FIGS. 16A-16B). In yet further embodiments, the removal process includes performing an etching process (e.g., a dry etch), a mechanical grinding process, or some other suitable removal process. Further, the removal process removes at least a portion of the isolation structure 704.

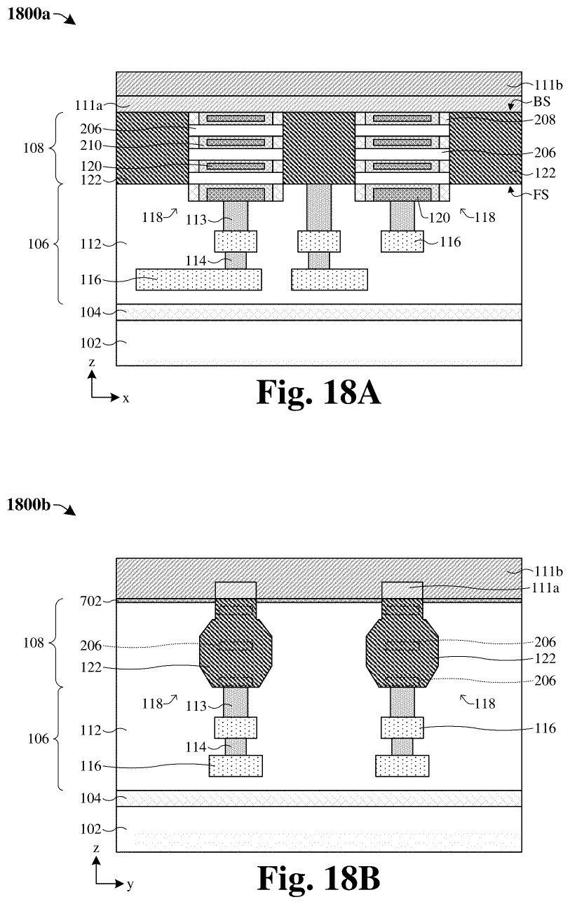

As shown in cross-sectional views 1800a and 1800b of FIGS. 18A-18B, the isolation structure (704 of FIG. 17B) is removed and a second high thermal conductivity layer 111b is formed on a backside BS of the semiconductor devices 118. In some embodiments, the isolation structure (704 of FIG. 17B) is removed by a wet etch process, a dry etch process, some other suitable removal process, or the like. In some embodiments, the second high thermal conductivity layer 111b may, for example, be or comprise aluminum nitride, boron nitride, yttrium oxide, yttrium aluminum garnet, aluminum oxide, beryllium oxide, silicon carbide, graphene, diamond like carbon, diamond, another suitable material, or any combination of the foregoing. In various embodiments, the second high thermal conductivity layer 111b has a thermal conductivity greater than about 10 W/m-K, within a range of about 10 to 2,500 W/m-K, or some other suitable value. The thermal conductivity of the second high thermal conductivity layer 111b is greater than a thermal conductivity of the one or more ILD layers of the first dielectric structure 112.

In some embodiments, the second high thermal conductivity layer 111b is formed on the semiconductor devices 118 by, for example, a CVD process, a thermal CVD process, a HPCVD process, a PECVD process, a MWCVD process, a PVD process, a thermal ALD process, a PEALD process, or some other suitable deposition or growth process. Further, the second high thermal conductivity layer 111b is formed or deposited at a low processing temperature that is, for example, less than about 400 degrees Celsius, within a range of about 100 to 400 degrees Celsius, or some other suitable temperature. Depositing (e.g., by CVD, PVD, ALD, etc.) the second high thermal conductivity layer 111b at the low processing temperature (e.g., less than about 400 degrees Celsius) facilitates the second high thermal conductivity layer 111b having a relatively high thermal conductivity (e.g., greater than about 10 W/m-K) while preventing damage (e.g., delamination, device damage, etc.) to the plurality of semiconductor devices 118 and/or layers within the first interconnect structure 106. In addition, the second high thermal conductivity layer 111b is formed with a crystalline structure (e.g., a single crystalline structure, a polycrystalline structure, an amorphous structure, etc.) that facilitates dissipating heat across the second high thermal conductivity layer 111b. In yet further embodiments, after depositing the second high thermal conductivity layer 111b over the semiconductor devices 118, a planarization process (e.g., a CMP process) is performed on the second high thermal conductivity layer 111b such that a top surface of the second high thermal conductivity layer 111b is substantially flat. In some embodiments, the first high thermal conductivity layer 111a and the second high thermal conductivity layer 111b comprise a same material. In further embodiments, a material of the first high thermal conductivity layer 111a is different from a material of the second high thermal conductivity layer 111b. In yet further embodiments, the second high thermal conductivity layer 111b may be deposited at a processing temperature within a range of about 100 to 1,400 degrees Celsius.

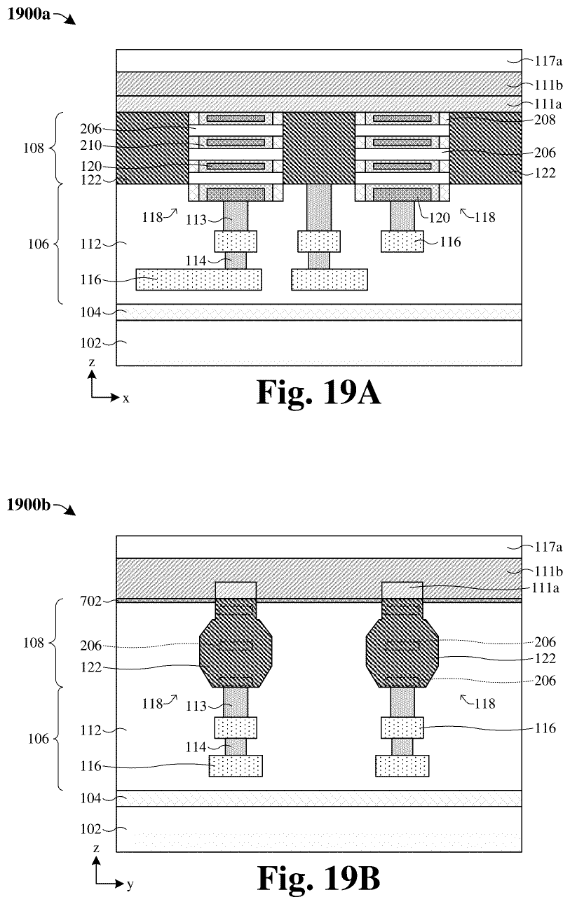

As shown in cross-sectional views 1900a and 1900b of FIGS. 19A-19B, a first dielectric layer 117a is formed on the second high thermal conductivity layer 111b. The first dielectric layer 117a is formed on the second high thermal conductivity layer 111b by, for example, a CVD process, a PVD process, an ALD process, or some other suitable deposition or growth process. The first dielectric layer 117a may, for example, be or comprise an oxide such as silicon dioxide or some other suitable material. In some embodiments, a thermal conductivity of the first dielectric layer 117a is less than about 1 W/m-K and is less than the thermal conductivities of the first and second high thermal conductivity layers 111a, 111b.

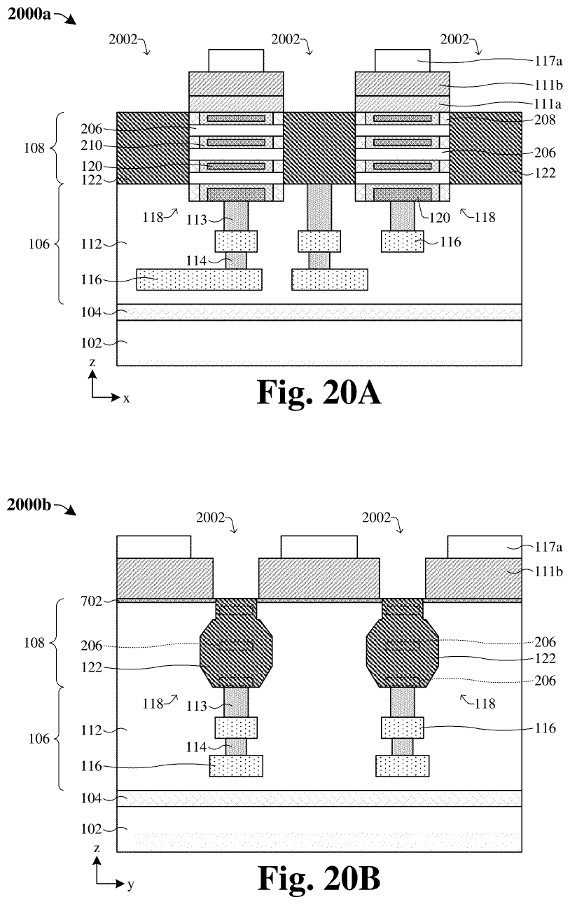

As shown in cross-sectional views 2000a and 2000b of FIGS. 20A-20B, a patterning process is performed on the first and second high thermal conductivity layers 111a, 111b and the first dielectric layer 117a to form a plurality of openings 2002 over the source/drain regions 122. In some embodiments, the patterning process includes: forming a masking layer (not shown) over the first dielectric layer 117a; performing an etching process (e.g., a dry etch, a wet etch, etc.) into the first and second high thermal conductivity layers 111a, 111b and the first dielectric layer 117a, thereby defining the plurality of openings 2002; and performing a removal process to remove the masking layer.

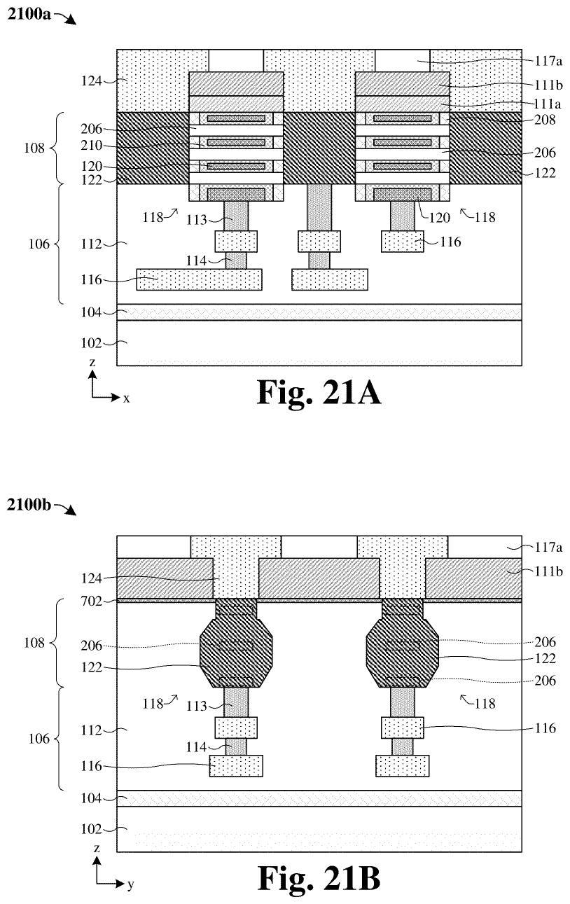

As shown in cross-sectional views 2100a and 2100b of FIGS. 21A-21B, a plurality of second conductive contacts 124 are formed in the plurality of openings (2002 of FIGS. 20A-20B). In some embodiments, forming the second conductive contacts 124 includes depositing (e.g., by CVD, PVD, sputtering, electroplating, etc.) one or more conductive materials (e.g., titanium nitride, titanium, aluminum, titanium aluminum, molybdenum, ruthenium, titanium nitride, tantalum nitride, etc.) in the openings (2002 of FIGS. 20A-20B) and performing a planarization process (e.g., a CMP process) on the one or more conductive materials. In various embodiments, the second conductive contacts 124 comprise a conductive liner layer disposed around a conductive core structure (e.g., as illustrated and/or described in FIGS. 9A-9B). In such embodiments, forming the second conductive contacts 124 comprises: depositing (e.g., by CVD, PVD, etc.) a conductive liner layer lining the openings (2002 of FIGS. 20A-20B); depositing (e.g., by CVD, PVD, sputtering, electroplating, etc.) a conductive core structure over the conductive liner layer; and performing a planarization process into the conductive liner layer and the conductive core structure.

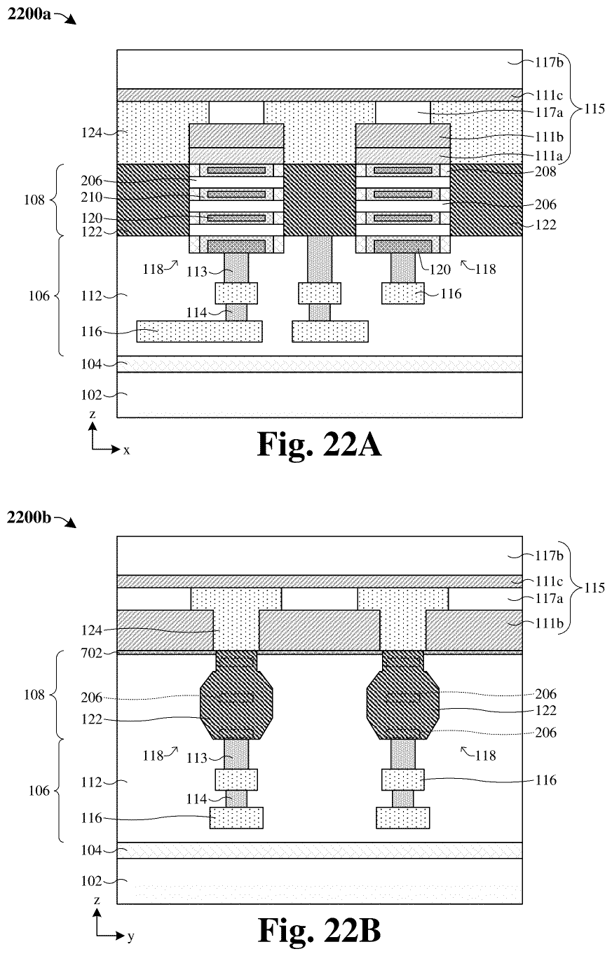

As shown in cross-sectional views 2200a and 2200b of FIGS. 22A-22B, a third high thermal conductivity layer 111c and a second dielectric layer 117b are formed on the plurality of second conductive contacts 124, thereby defining a second dielectric structure 115. In some embodiments, the third high thermal conductivity layer 111c is formed on the second conductive contacts 124 by, for example, a CVD process, a thermal CVD process, a HPCVD process, a PECVD process, a MWCVD process, a PVD process, a thermal ALD process, a PEALD process, or some other suitable deposition or growth process. Further, the third high thermal conductivity layer 111c is formed or deposited at a low processing temperature that is, for example, less than about 400 degrees Celsius, within a range of about 100 to 400 degrees Celsius, or some other suitable temperature. Depositing (e.g., by CVD, PVD, ALD, etc.) the third high thermal conductivity layer 111c at the low processing temperature (e.g., less than about 400 degrees Celsius) facilitates the third high thermal conductivity layer 111c having a relatively high thermal conductivity (e.g., greater than about 10 W/m-K) while preventing damage (e.g., delamination, device damage, etc.) to the plurality of semiconductor devices 118.

The second dielectric layer 117b is formed on the third high thermal conductivity layer 111c by, for example, a CVD process, a PVD process, an ALD process, or some other suitable deposition or growth process. The second dielectric layer 117b may, for example, be or comprise an oxide such as silicon dioxide or some other suitable material. In some embodiments, a thermal conductivity of the second dielectric layer 117b is less than about 1 W/m-K and is less than the thermal conductivities of the first, second, and third high thermal conductivity layers 111a-c.

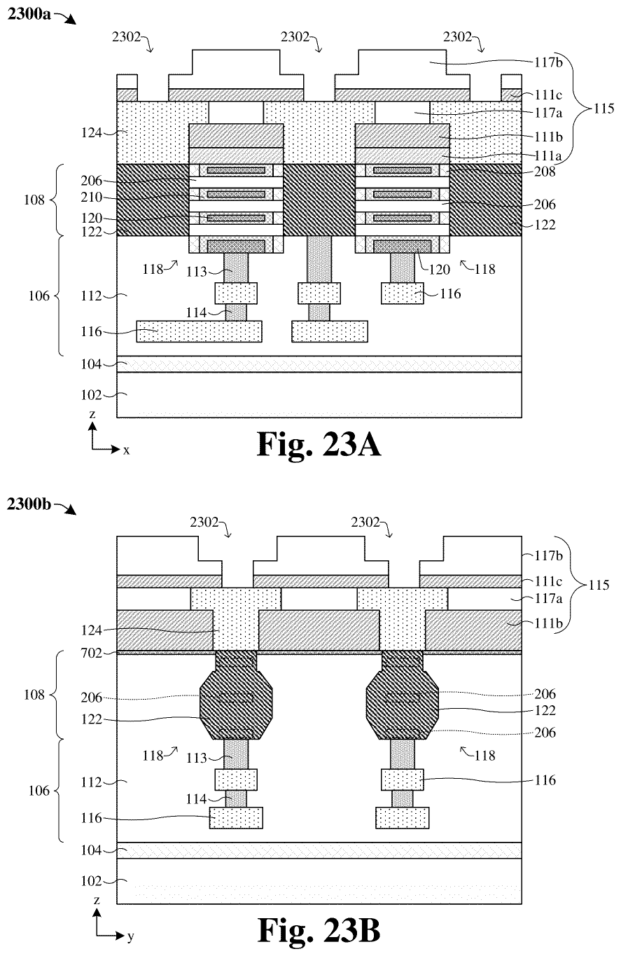

As shown in cross-sectional views 2300a and 2300b of FIGS. 23A-23B, a patterning process is performed on the third high thermal conductivity layer 111c and the second dielectric layer 117b, thereby forming a plurality of openings 2302. In some embodiments, the patterning process includes: forming a masking layer (not shown) over the second dielectric layer 117b; performing an etching process (e.g., a dry etch, a wet etch, etc.) into the third high thermal conductivity layer 111c and the second dielectric layer 117b, thereby defining the plurality of openings 2302; and performing a removal process to remove the masking layer.

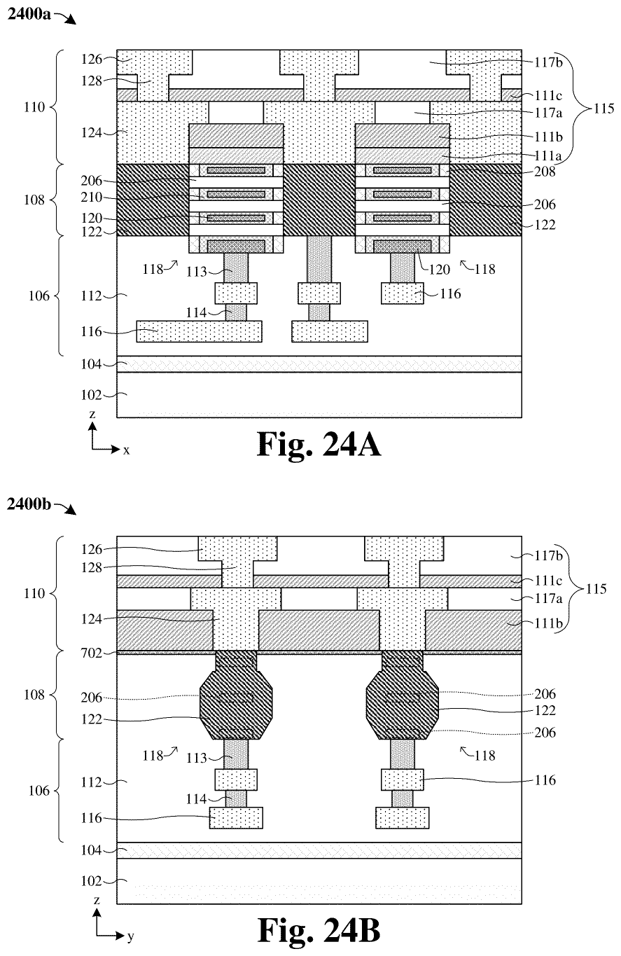

As shown in cross-sectional views 2400a and 2400b of FIGS. 24A-24B, a plurality of second conductive vias 128 and a plurality of second conductive wires 126 are formed in the plurality of openings (2302 of FIGS. 23A-23B), thereby forming a second interconnect structure 110. In some embodiments, forming the second conductive vias and wires 128, 126 includes depositing (e.g., by CVD, PVD, sputtering, electroplating, etc.) one or more conductive materials (e.g., titanium nitride, titanium, aluminum, titanium aluminum, molybdenum, ruthenium, etc.) in the openings (2302 of FIGS. 23A-23B) and performing a planarization process (e.g., a CMP process) on the one or more conductive materials. In various embodiments, the second conductive vias and wires 128, 126 comprise a conductive liner layer disposed around a conductive core structure (e.g., as illustrated and/or described in FIGS. 9A-9B). In yet further embodiments, while a single via level and a single wire level are shown, the processing steps of FIGS. 23A-24B may be repeated to form additional via and/or wire levels.

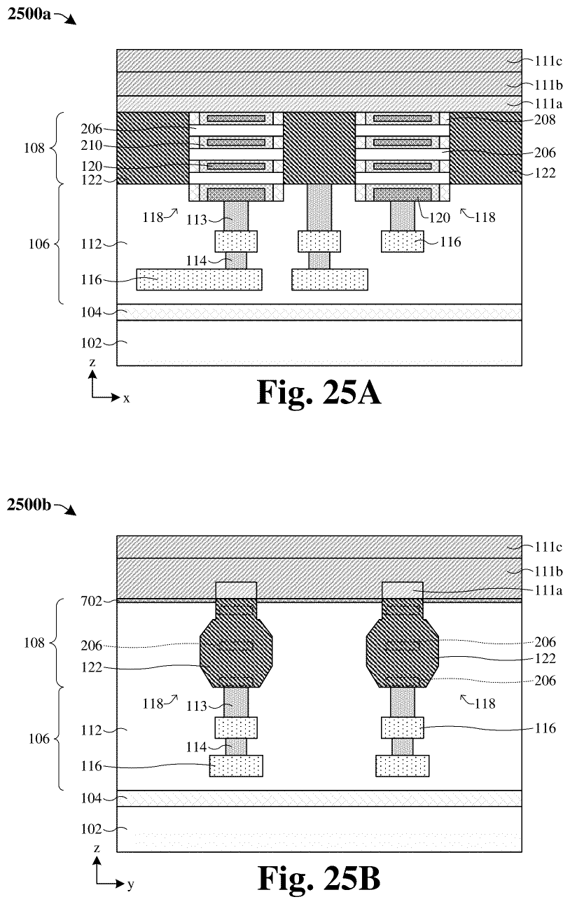

FIGS. 25A-25B through 27A-27B illustrate various cross-sectional views of some embodiments of acts that may be performed in place of the acts at FIGS. 19A-19B through 24A-24B, such that the method of FIGS. 11 through 24A-24B may alternatively proceed from FIGS. 11 through 18A-18B to FIGS. 25A-25B through 27A-27B (i.e., skipping FIGS. 19A-19B through 24A-24B). In various embodiments, FIGS. 25A-25B through 27A-27B illustrate various cross-sectional views of some other embodiments of forming the second interconnect structure 110. Although the cross-sectional views shown in FIGS. 25A-25B through 27A-27B are described with reference to a method, it will be appreciated that the structures shown in FIGS. 25A-25B through 27A-27B are not limited to the method but rather may stand alone separate of the method. In addition, figures with a suffix of “A” illustrate a cross-sectional view taken along the z-x plane and figures with a suffix of “B” illustrate a cross-sectional view taken along the z-y plane.

As shown in cross-sectional views 2500a and 2500b of FIGS. 25A-25B, a third high thermal conductivity layer 111c is formed over the second high thermal conductivity layer 111b. In various embodiments, the third high thermal conductivity layer 111c is formed by the process(es) described above regarding the formation of the second high thermal conductivity layer 111b in FIGS. 18A-18B. For example, the third high thermal conductivity layer 111c is formed by a CVD process, a thermal CVD process, a HPCVD process, a PECVD process, a MWCVD process, a PVD process, a thermal ALD process, a PEALD process, or some other suitable deposition or growth process at a low processing temperature (e.g., less than about 400 degrees Celsius). In some embodiments, the third high thermal conductivity layer 111c may, for example, be or comprise aluminum nitride, boron nitride, yttrium oxide, yttrium aluminum garnet, aluminum oxide, beryllium oxide, silicon carbide, graphene, diamond like carbon, diamond, another suitable material, or any combination of the foregoing. In various embodiments, the third high thermal conductivity layer 111c has a thermal conductivity greater than about 10 W/m-K, within a range of about 10 to 2,500 W/m-K, or some other suitable value. In further embodiments, the third high thermal conductivity layer 111c comprises a same material as the first high thermal conductivity layer 111a and/or the second high thermal conductivity layer 111b.

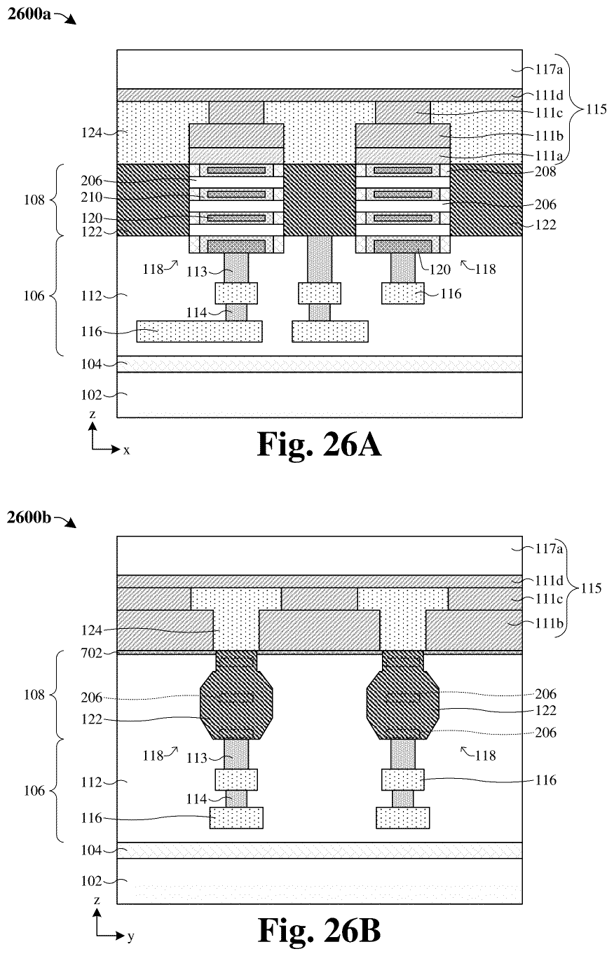

As shown in cross-sectional views 2600a and 2600b of FIGS. 26A-26B, a plurality of second conductive contacts 124 are formed over the source/drain regions 122. Further, a fourth high thermal conductivity layer 111d and a first dielectric layer 117a is formed over the plurality of second conductive contacts 124, thereby forming or defining a second dielectric structure 115. In some embodiments, the plurality of second conductive contacts 124 are formed by the process(es) described above in FIGS. 20A-20B through 21A-21B. For example, a process for forming the second conductive contacts 124 includes: patterning the first, second, and third high thermal conductivity layers 111a-c to form openings over the source/drain regions 122; depositing one or more conductive materials in the openings; and performing a planarization process on the one or more conductive materials.

In some embodiments, the fourth high thermal conductivity layer 111d is formed by the process(es) described above regarding the formation of the second high thermal conductivity layer 111b in FIGS. 18A-18B. In some embodiments, the fourth high thermal conductivity layer 111d may, for example, be or comprise aluminum nitride, boron nitride, yttrium oxide, yttrium aluminum garnet, aluminum oxide, beryllium oxide, silicon carbide, graphene, diamond like carbon, diamond, another suitable material, or any combination of the foregoing. In various embodiments, the fourth high thermal conductivity layer 111d has a thermal conductivity greater than about 10 W/m-K, within a range of about 10 to 2,500 W/m-K, or some other suitable value. In some embodiments, the first dielectric layer 117a is deposited by CVD, PVD, ALD, etc. and comprises a dielectric material (e.g., silicon dioxide) having a thermal conductivity less than that of the fourth high thermal conductivity layer 111d.

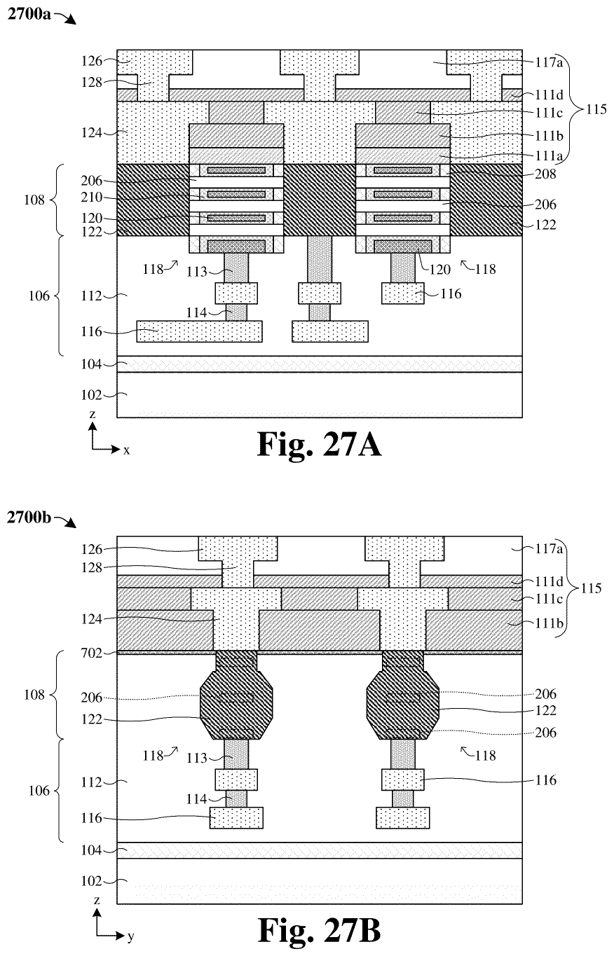

As shown in cross-sectional view 2700a and 2700b of FIGS. 27A-27B, a plurality of second conductive vias 128 and a plurality of second conductive wires 126 are formed in the fourth high thermal conductivity layer 111d and the first dielectric layer 117a. In some embodiments, the plurality of second conductive vias 128 and the plurality of second conductive wires 126 are formed by the process(es) described above in FIGS. 23A-23B through 24A-24B.

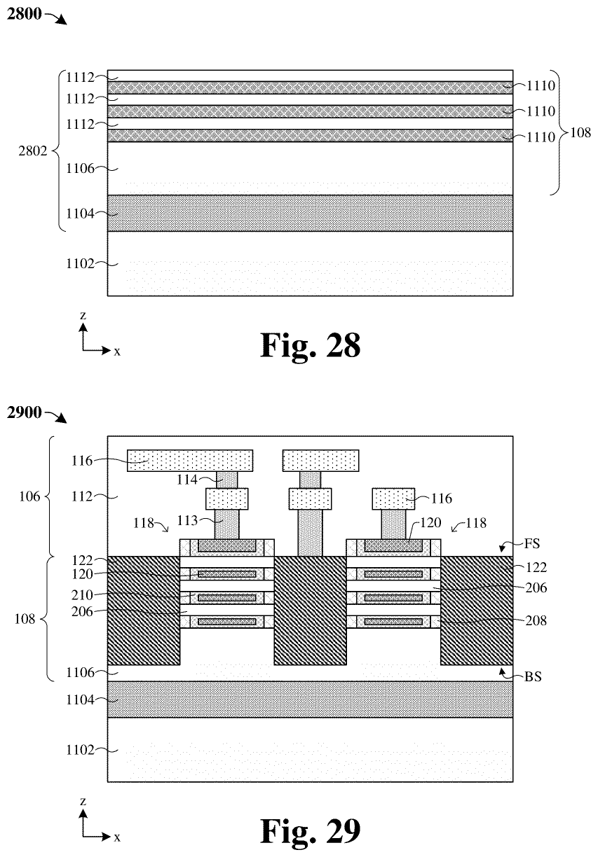

FIGS. 28 through 37A-37B illustrate various cross-sectional views of some embodiments of a method for forming an IC structure comprising and interconnect structure having one or more high thermal conductivity layers. Although FIGS. 28 through 37A-37B are described in relation to a method, it will be appreciated that the structures disclosed in the method are not limited to the method, but instead may stand alone as structures independent of the method. Further, although FIGS. 28 through 37A-37B are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part. In addition, figures with a suffix of “A” illustrate a cross-sectional view taken along the z-x plane and figures with a suffix of “B” illustrate a cross-sectional view taken along the z-y plane.

As shown in cross-sectional view 2800 of FIG. 28, a base substrate 1102 is provided and a stack of layers 2802 is formed over the base substrate 1102. In some embodiments, the stack of layers 2802 includes an etch stop layer 1104 on the base substrate 1102, a lower semiconductor layer 1106 on the etch stop layer 1104, a plurality of first semiconductor layers 1110, and a plurality of second semiconductor layers 1112. The plurality of first semiconductor layers 1110 and the plurality of second semiconductor layers 1112 are alternatingly stacked with one another. In various embodiments, the plurality of second semiconductor layers 1112 and the lower semiconductor layer 1106 are part of or define a device layer 108. In various embodiments, individual layers of the stack of layers 2802 may each be formed by one or more growth or deposition processes such as, for example, a CVD process, a PVD process, an ALD process, an epitaxial process (e.g., MBE, VPE, LPE, etc.), or some other suitable growth or deposition process.

As shown in cross-sectional view 2900 of FIG. 29, a plurality of semiconductor devices 118 are formed over the base substrate 1102 and a first interconnect structure 106 is formed on a frontside FS of the semiconductor devices 118. In various embodiments, the semiconductor devices 118 are GAA FETs and respectively comprise a plurality of semiconductor channels 206, a gate dielectric structure 210, a gate electrode 120, a spacer layer 208, and source/drain regions 122. In various embodiments, the plurality of semiconductor devices 118 are formed by process(es) substantially similar to the process(es) described above in FIGS. 12 and 13 (where the patterning process utilized to form the semiconductor channels 206 over etches into the lower semiconductor layer 1106).

The first interconnect structure 106 comprises a plurality of first conductive contacts 113, a plurality of first conductive wires 116, and a plurality of first conductive vias 114 disposed within a first dielectric structure 112. In some embodiments, conductive structures of the first interconnect structure 106 may each be formed by a damascene process (e.g., a single damascene process or a dual damascene process) or some other suitable process. In further embodiments, the first dielectric structure 112 comprises one or more inter-level dielectric (ILD) layers that may, for example, each be formed by CVD, PVD, ALD, or some other suitable growth or deposition process.

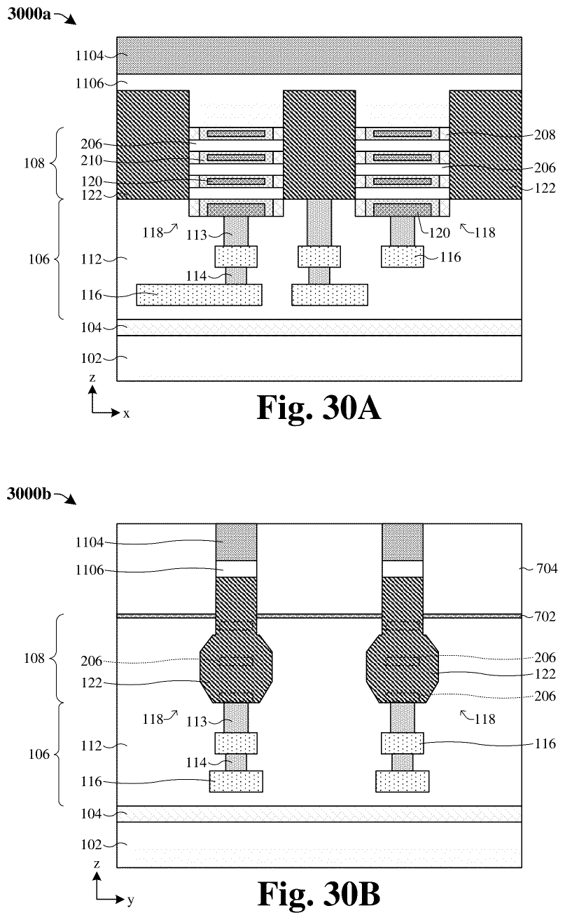

As shown in cross-sectional views 3000a and 3000b of FIGS. 30A-30B, the structure of FIG. 29 is flipped and a carrier substrate 102 is bonded to the first interconnect structure 106 and a thinning process is performed to remove the base substrate (1102 of FIG. 29) from over the etch stop layer 1104. In some embodiments, bonding the carrier substrate 102 to the first interconnect structure includes forming an insulator layer 104 on the carrier substrate 102 and bonding the insulating layer 104 to the first interconnect structure 106. In various embodiments, the thinning process includes performing a mechanical grinding process, a CMP process, an etching process, or some other suitable process into the base substrate (1102 of FIG. 29) until the etch stop layer 1104 is reached.

Further, shown in FIG. 30B, in some embodiments, an isolation structure 704 is disposed along sidewalls of the lower semiconductor layer 1106 and sidewalls of the etch stop layer 1104. In various embodiments, the isolation structure 704 is formed (e.g., by CVD, PVD, etc.) after the patterning process utilized to form the semiconductor channels 206. Further, a lower etch stop layer 702 is disposed along the first dielectric structure 112. In some embodiments, the lower etch stop layer 702 is formed (e.g., by CVD, PVD, etc.) after forming the semiconductor devices 118 and before forming the first interconnect structure 106.

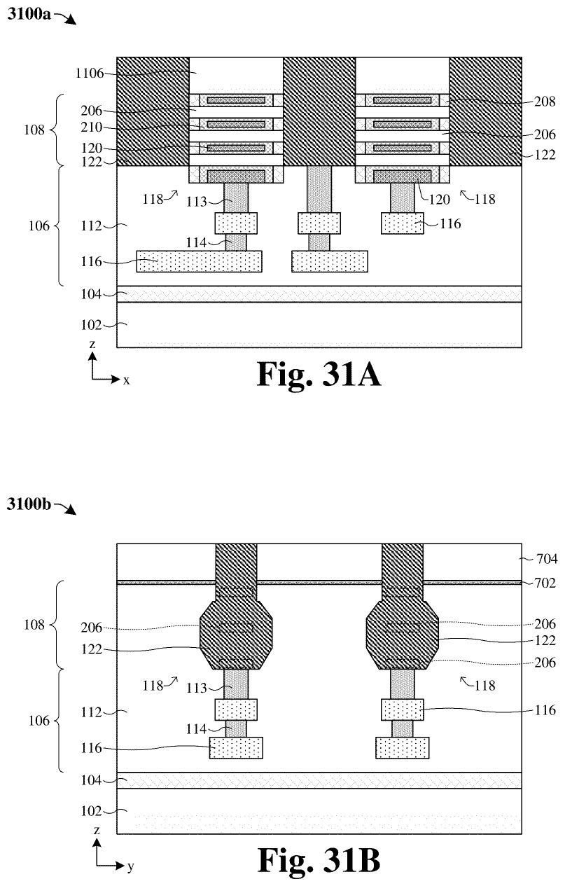

As shown in cross-sectional views 3100a and 3100b of FIGS. 31A-31B, a removal process is performed to remove the etch stop layer (1104 of FIGS. 30A-30B) and at least a portion of the lower semiconductor layer 1106. In some embodiments, the removal process includes depositing (e.g., by CVD, PVD, etc.) a sacrificial oxide (e.g., silicon dioxide) over the etch stop layer (1104 of FIGS. 30A-30B) (not shown) and performing a planarization process (e.g., a CMP process) into the sacrificial oxide, the etch stop layer (1104 of FIGS. 30A-30B), and the lower semiconductor layer 1106. In further embodiments, the removal process includes performing an etching process (e.g., a dry etch), a mechanical grinding process, or some other suitable removal process.

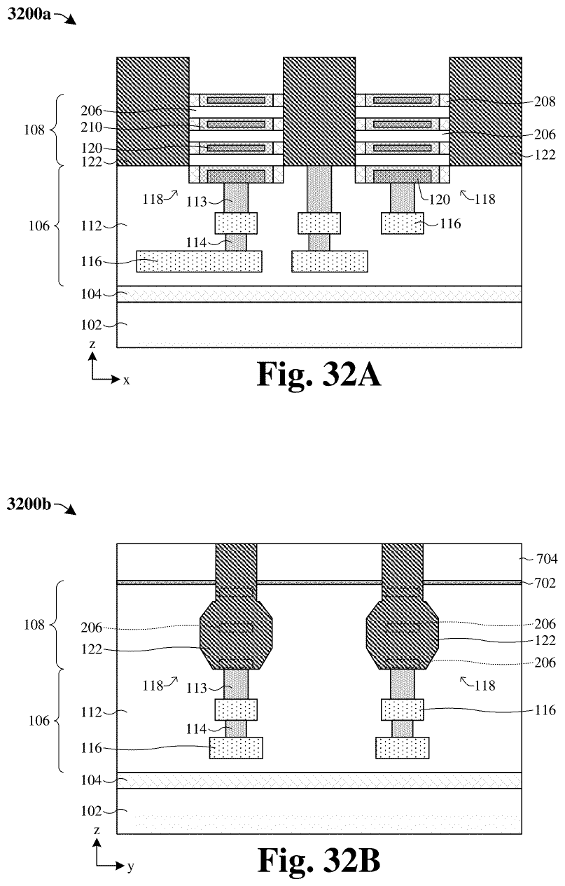

As shown in cross-sectional views 3200a and 3200b of FIGS. 32A-32B, an etching process is performed to remove the lower semiconductor layer (1106 of FIGS. 31A-31B) from over the semiconductor devices 118. In various embodiments, the etching process includes exposing the lower semiconductor layer (1106 of FIGS. 31A-31B) to a wet etchant such as, for example, hydrogen peroxide (e.g., H₂O₂), ammonium hydroxide (e.g., NH₄OH), nitric acid (e.g., HNO₃), some other suitable etchant, or any combination of the foregoing.

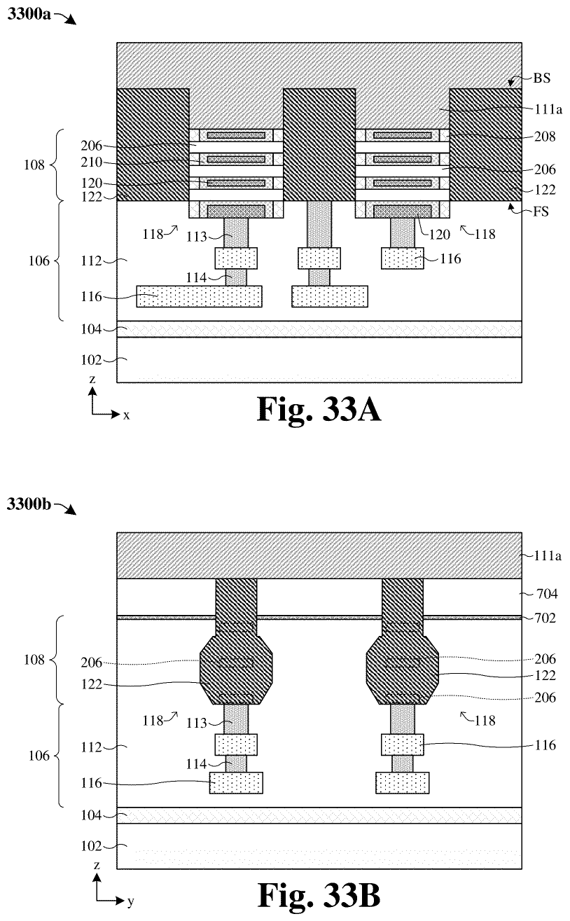

As shown in cross-sectional views 3300a and 3300b of FIGS. 33A-33B, a first high thermal conductivity layer 111a is formed on a backside BS of the semiconductor devices 118. In some embodiments, the first high thermal conductivity layer 111a is formed on the semiconductor devices 118 by, for example, a CVD process, a thermal CVD process, a HPCVD process, a PECVD process, a MWCVD process, a PVD process, a thermal ALD process, a PEALD process, or some other suitable deposition or growth process. Further, the first high thermal conductivity layer 111a is formed or deposited at a low processing temperature that is, for example, less than about 400 degrees Celsius, within a range of about 100 to 400 degrees Celsius, or some other suitable temperature. Depositing (e.g., by CVD, PVD, ALD, etc.) the first high thermal conductivity layer 111a at the low processing temperature (e.g., less than about 400 degrees Celsius) facilitates the third high thermal conductivity layer 111c having a relatively high thermal conductivity (e.g., greater than about 10 W/m-K) while preventing damage (e.g., delamination, device damage, etc.) to the plurality of semiconductor devices 118.

In some embodiments, the first high thermal conductivity layer 111a may, for example, be or comprise aluminum nitride, boron nitride, yttrium oxide, yttrium aluminum garnet, aluminum oxide, beryllium oxide, silicon carbide, graphene, diamond like carbon, diamond, another suitable material, or any combination of the foregoing. In various embodiments, the first high thermal conductivity layer 111a has a thermal conductivity greater than about 10 W/m-K, within a range of about 10 to 2,500 W/m-K, or some other suitable value.

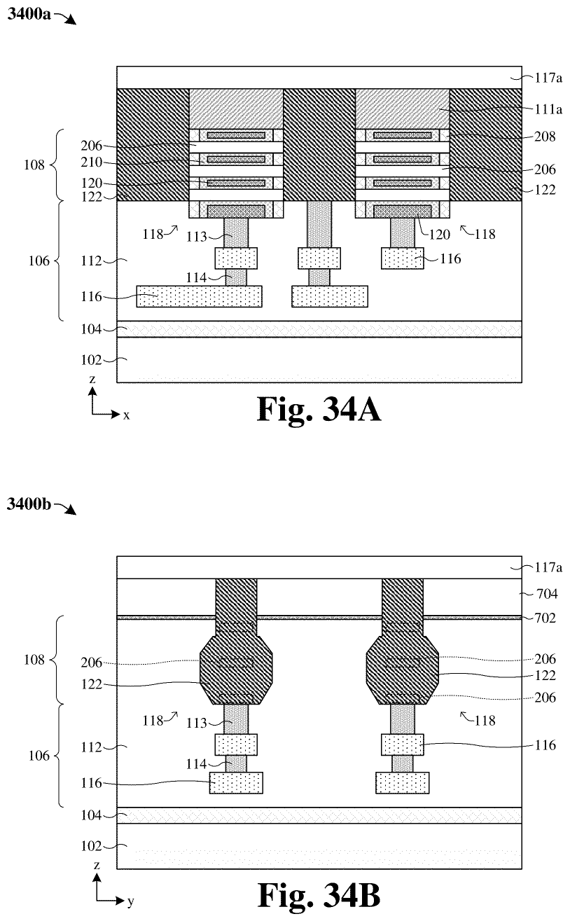

As shown in cross-sectional views 3400a and 3400b of FIGS. 34A-34B, a planarization process (e.g., a CMP process) is performed on the first high thermal conductivity layer 111a and a first dielectric layer 117a is formed on the first high thermal conductivity layer 111a. In various embodiments, after the planarization process a top surface of the first high thermal conductivity layer 111a is coplanar with a top surface of the source/drain regions 122. Further, the first dielectric layer 117a is formed on the first high thermal conductivity layer 111a by, for example, a CVD process, a PVD process, an ALD process, or some other suitable deposition or growth process. The first dielectric layer 117a may, for example, be or comprise an oxide such as silicon dioxide or some other suitable material. In some embodiments, a thermal conductivity of the first dielectric layer 117a is less than about 1 W/m-K and is less than the thermal conductivity of the first high thermal conductivity layer 111a.

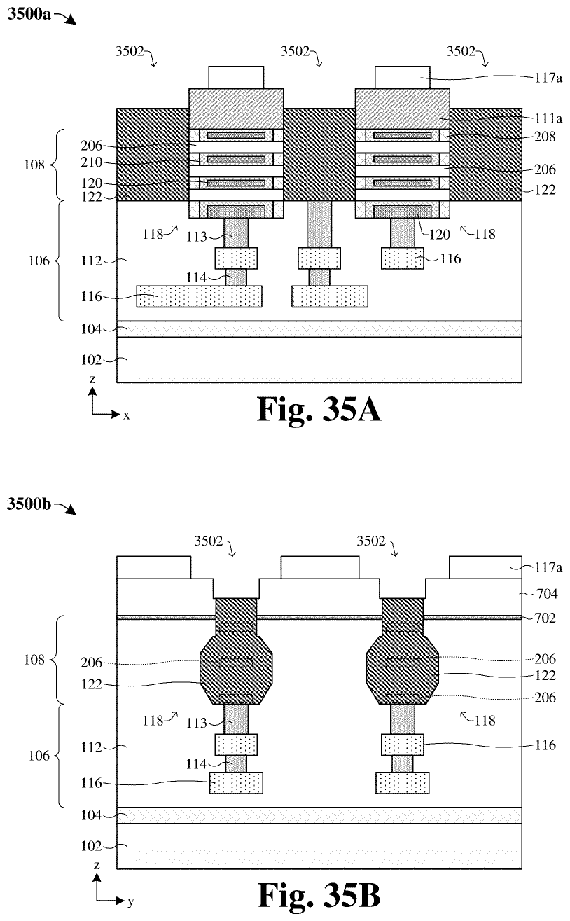

As shown in cross-sectional views 3500a and 3500b of FIGS. 35A-35B, a patterning process is performed on the first dielectric layer 117a and the first high thermal conductivity layer 111a to form a plurality of openings 3502 over the source/drain regions 122. In some embodiments, the patterning process includes: forming a masking layer (not shown) over the first dielectric layer 117a; performing an etching process (e.g., a dry etch, a wet etch, etc.) into the first dielectric layer 117a and the first high thermal conductivity layer 111a, thereby defining the plurality of openings 3502; and performing a removal process to remove the masking layer.

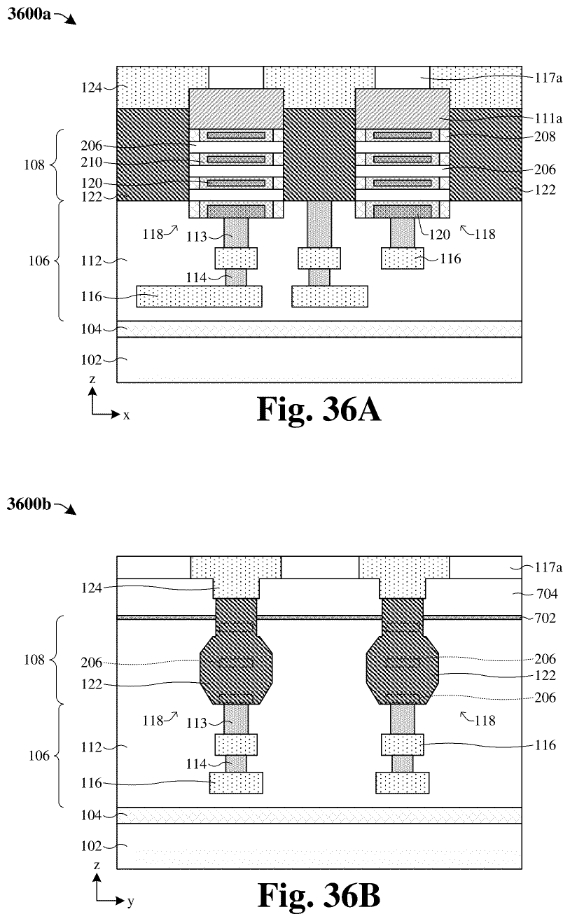

As shown in cross-sectional views 3600a and 3600b of FIGS. 36A-36B, a plurality of second conductive contacts 124 are formed in the plurality of openings (3502 of FIGS. 35A-35B). In some embodiments, forming the second conductive contacts 124 includes depositing (e.g., by CVD, PVD, sputtering, electroplating, etc.) one or more conductive materials (e.g., titanium nitride, titanium, aluminum, titanium aluminum, molybdenum, ruthenium, etc.) in the openings (3502 of FIGS. 35A-35B) and performing a planarization process (e.g., a CMP process) on the one or more conductive materials. In various embodiments, the second conductive contacts 124 comprise a conductive liner layer disposed around a conductive core structure (e.g., as illustrated and/or described in FIGS. 9A-9B).

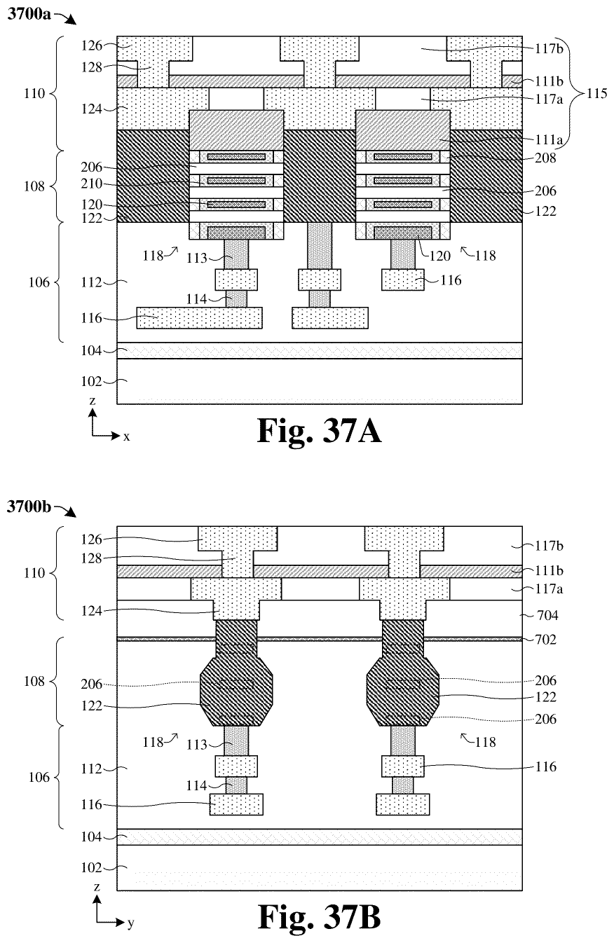

As shown in cross-sectional views 3700a and 3700b of FIGS. 37A-37B, a second high thermal conductivity layer 111b and a second dielectric layer 117b are formed over the plurality of second conductive contacts 124, thereby defining a second dielectric structure 115. Further, a plurality of second conductive vias 128 and a plurality of second conductive wires 126 are formed in the second dielectric structure 115, thereby defining a second interconnect structure 110.

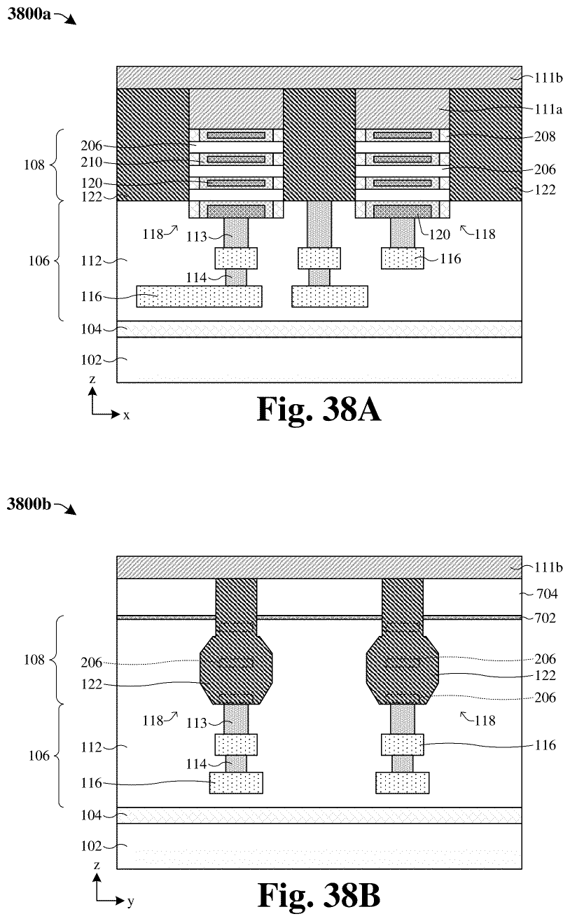

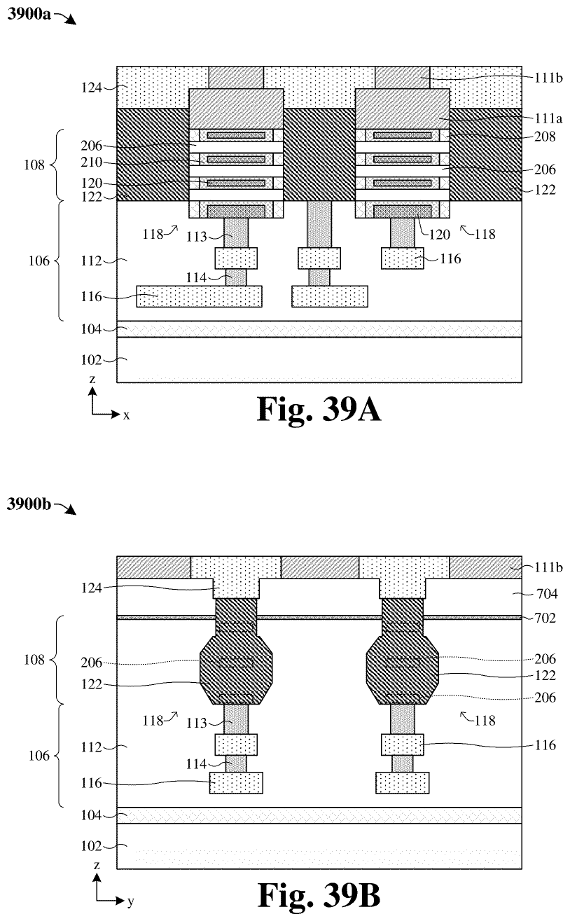

FIGS. 38A-38B through 39A-39B illustrate various cross-sectional views of some embodiments of acts that may be performed in place of the acts at FIGS. 34A-34B through 36A-36B, such that the method of FIGS. 28 through 37A-37B may alternatively proceed from FIGS. 28 through 33A-33B to FIGS. 38A-38B through 39A-39B, and then from FIGS. 39A-39B to FIGS. 37A-37B (skipping FIGS. 34A-34B through 36A-36B).

As shown in cross-sectional views 3800a and 3800b of FIGS. 38A-38B, a planarization process (e.g., a CMP process) is performed on the first high thermal conductivity layer 111a and a second high thermal conductivity layer 111b is formed on the first high thermal conductivity layer 111a. In various embodiments, the second high thermal conductivity layer 111b is formed by the process(es) described above regarding the formation of the first high thermal conductivity layer 111a in FIGS. 33A-33B. In some embodiments, the second high thermal conductivity layer 111b comprises a same high thermal conductivity material as the first high thermal conductivity layer 111a. In other embodiments, the second high thermal conductivity layer 111b comprises a high thermal conductivity material different from that of the first high thermal conductivity layer 111a.

As shown in cross-sectional views 3900a and 3900b of FIGS. 39A-39B, a plurality of second conductive contacts 124 are formed in the first and second high thermal conductivity layers 111a and 111b. In various embodiments, the plurality of second conductive contacts 124 are formed by the process(es) described above in FIGS. 35A-35B through 36A-36B.

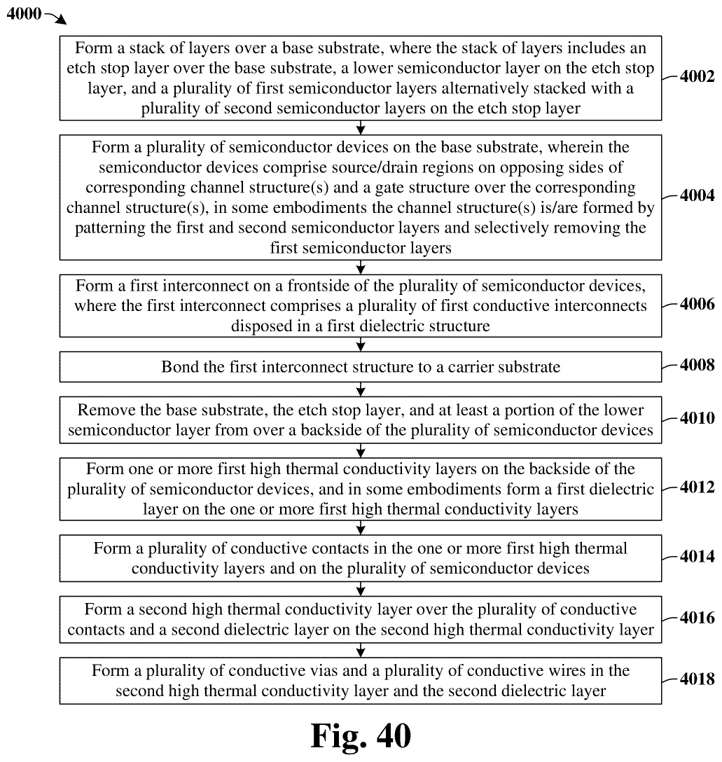

FIG. 40 illustrates a flow diagram of some embodiments of a method 4000 of forming an IC structure comprising an interconnect structure having one or more high thermal conductivity layers. While method 4000 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 4002, a stack of layers is formed over a base substrate. The stack of layers includes an etch stop layer over the base substrate, a lower semiconductor layer on the etch stop layer, and a plurality of first semiconductor layers alternatively stacked with a plurality of second semiconductor layers on the etch stop layer. FIG. 11 illustrates a cross-sectional view 1100 of some embodiments corresponding to act 4002. FIG. 28 illustrates a cross-sectional view 2800 of some other embodiments corresponding to act 4002.

At act 4004, a plurality of semiconductor devices are formed on the base substrate. The semiconductor devices comprises source/drain regions on opposing sides of corresponding channel structure(s) and a gate structure over the corresponding channel structure(s). In some embodiments, the channel structure(s) is/are formed by patterning the first and second semiconductor layers and selectively removing the first semiconductor layers. FIGS. 12 and 13 illustrate cross-sectional views 1200 and 1300 of some embodiments corresponding to act 4004. FIG. 29 illustrates a cross-sectional view 2900 of some other embodiments corresponding to act 4004.

At act 4006, a first interconnect structure is formed on a frontside of the plurality of semiconductor devices, where the first interconnect structure comprises a plurality of first conductive interconnects disposed in a first dielectric structure. FIG. 14 illustrates a cross-sectional view 1400 of some embodiments corresponding to act 4006. FIG. 29 illustrates a cross-sectional view 2900 of some other embodiments corresponding to act 4006.

At act 4008, the first interconnect structure is bonded to a carrier substrate. FIG. 15 illustrates a cross-sectional view 1500 of some embodiments corresponding to act 4008. FIGS. 30A-30B illustrate cross-sectional views 3000a-b of some other embodiments corresponding to act 4008.

At act 4010, the base substrate, the etch stop layer, and at least a portion of the lower semiconductor layer are removed from over a backside of the plurality of semiconductor devices. FIGS. 16A-16B and 17A-17B illustrate cross-sectional views 1600a-b and 1700a-b of some embodiments corresponding to act 4010. FIGS. 30A-30B and 31A-31B illustrate cross-sectional views 3000a-b and 3100a-b of some other embodiments corresponding to act 4010.

At act 4012, one or more first high thermal conductivity layers are formed on the backside of the plurality of semiconductor devices. In some embodiments, a first dielectric layer is formed on the one or more first high thermal conductivity layers. FIGS. 18A-18B and 19A-19B illustrate cross-sectional views 1800a-b and 1900a-b of some embodiments corresponding to act 4012. FIGS. 33A-33B and 34A-34B illustrate cross-sectional views 3300a-b and 3400a-b of some other embodiments corresponding to act 4012.

At act 4014, a plurality of conductive contacts are formed in the one or more first high thermal conductivity layers and on the plurality of semiconductor devices. FIGS. 20A-20B and 21A-21B illustrate cross-sectional views 2000a-b and 2100a-b of some embodiments corresponding to act 4014. FIGS. 35A-35B and 36A-36B illustrate cross-sectional views 3500a-b and 3600a-b of some other embodiments corresponding to act 4014.

At act 4016, a second high thermal conductivity layer is formed over the plurality of conductive contacts and a second dielectric layer is formed on the second high thermal conductivity layer. FIGS. 22A-22B illustrate cross-sectional views 2200a-b of some embodiments corresponding to act 4016. FIGS. 37A-37B illustrate cross-sectional views 3700a-b of some other embodiments corresponding to act 4016.

At act 4018, a plurality of conductive vias and a plurality of conductive wires are formed in the second high thermal conductivity layer and the second dielectric layer. FIGS. 23A-B and 24A-B illustrate cross-sectional views 2300a-b and 2400a-b of some embodiments corresponding to act 4018. FIGS. 37A-37B illustrate cross-sectional views 3700a-b of some other embodiments corresponding to act 4018.

Accordingly, the present disclosure relates to an IC structure comprising a first interconnect structure on a frontside of a plurality of semiconductor devices and a second interconnect structure on a backside of the semiconductor devices, where the second interconnect structure comprises one or more high thermal conductivity layers disposed on the semiconductor devices and configured to increase thermal dissipation performance of the IC structure.

In some embodiments, the present disclosure relates to an integrated circuit (IC) structure. The IC structure includes a semiconductor device having a frontside and a backside opposite the frontside; a first interconnect structure on the frontside of the semiconductor device, wherein the first interconnect structure comprises a first dielectric structure having a plurality of inter-level dielectric (ILD) layers; and a second dielectric structure on the backside of the semiconductor device, wherein the second dielectric structure comprises a first high thermal conductivity layer having a thermal conductivity greater than that of the ILD layers. In some embodiments, the semiconductor device comprises a gate structure disposed between a pair of source/drain regions, wherein the first high thermal conductivity layer directly contacts the gate structure. In some embodiments, the first high thermal conductivity layer directly contacts opposing sidewalls of an individual source/drain region in the pair of source/drain regions. In some embodiments, the IC structure further includes a plurality of conductive contacts disposed in the first high thermal conductivity layer, wherein the conductive contacts are disposed on the source/drain regions. In some embodiments, the first high thermal conductivity layer directly contacts opposing sidewalls of the plurality of conductive contacts. In some embodiments, the second dielectric structure further comprises a first dielectric layer on the first high thermal conductivity layer and a second high thermal conductivity layer on the first dielectric layer, wherein a thermal conductivity of the first dielectric layer is less than that of the first and second high thermal conductivity layers. In some embodiments, a thickness of the first dielectric layer is less than a thickness of the first high thermal conductivity layer. In some embodiments, the thermal conductivity of the first high thermal conductivity layer is greater than or equal to about 10 W/m-K. In some embodiments, the first high thermal conductivity layer comprises one or more of aluminum nitride, boron nitride, yttrium oxide, yttrium aluminum garnet, aluminum oxide, beryllium oxide, silicon carbide, graphene, diamond like carbon, and diamond.

In some embodiments, the present disclosure relates to an integrated circuit (IC) structure. The IC structure includes a semiconductor device having a frontside and a backside opposite the frontside, wherein the semiconductor device comprises a gate structure between a pair of source/drain regions; a first interconnect structure on the frontside of the semiconductor device, wherein the first interconnect structure comprises a plurality of first conductive interconnects electrically coupled to the semiconductor device and disposed in a first dielectric structure; and a second interconnect structure on the backside of the semiconductor device, wherein the second interconnect structure comprises a plurality of second conductive interconnects disposed in a second dielectric structure, wherein the plurality of second conductive interconnects comprises a plurality of conductive contacts disposed on and electrically coupled to the source/drain regions, wherein the plurality of conductive contacts are disposed in a first high thermal conductivity layer of the second dielectric structure. In some embodiments, the semiconductor device comprises a channel structure abutting the gate structure and between the pair of source/drain regions, wherein the first high thermal conductivity layer directly contacts the gate structure or the channel structure. In some embodiments, the second dielectric structure further comprises a dielectric layer on the first high thermal conductivity layer, wherein a thermal conductivity of the first high thermal conductivity layer is greater than that of the dielectric layer. In some embodiments, the first high thermal conductivity layer has a crystal structure different from that of the dielectric layer. In some embodiments, the crystal structure of the first high thermal conductivity layer is cubic. In some embodiments, the second dielectric structure further comprises a second high thermal conductivity layer disposed along a bottom surface of the plurality of conductive contacts. In some embodiments, the first dielectric structure comprises an etch stop layer disposed between inter-level dielectric (ILD) layers, wherein a thermal conductivity of the first high thermal conductivity layer is greater than that of the etch stop layer.

In yet other embodiments, the present disclosure relates to a method of forming an integrated circuit (IC) structure. The method includes forming a stack of layers over a base substrate, wherein the stack of layers includes an etch stop layer over the base substrate and a lower semiconductor layer on the etch stop layer; forming a plurality of semiconductor devices on the lower semiconductor layer; forming a first interconnect structure on a frontside of the plurality of semiconductor devices, wherein the first interconnect structure comprises a plurality of first conductive interconnects disposed in a first dielectric structure; bonding the first interconnect structure to a carrier substrate; removing the base substrate, the etch stop layer, and the lower semiconductor layer from over a backside of the plurality of semiconductor devices, where the backside is opposite the frontside; and forming a first high thermal conductivity layer on the backside of the plurality of semiconductor devices. In some embodiments, a thermal conductivity of the first high thermal conductivity layer is greater than that of the etch stop layer. In some embodiments, the method further includes forming a plurality of conductive contacts in the first high thermal conductivity layer, wherein the conductive contacts contact the semiconductor devices. In some embodiments, the first high thermal conductivity layer is formed by physical vapor deposition (PVD), chemical vapor deposition (CVD), plasma-enhanced CVD (PECVD), or atomic layer deposition (ALD) at a temperature within a range of about 100 to 400 degrees Celsius.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a semiconductor device having a frontside and a backside opposite the frontside;
a first interconnect structure on the frontside of the semiconductor device, wherein the first interconnect structure comprises a first dielectric structure having a plurality of inter-level dielectric (ILD) layers; and
a second dielectric structure on the backside of the semiconductor device, wherein the second dielectric structure comprises a first high thermal conductivity layer having a thermal conductivity greater than that of the ILD layers.

2. The IC structure of claim 1, wherein the semiconductor device comprises a gate structure disposed between a pair of source/drain regions, wherein the first high thermal conductivity layer directly contacts the gate structure.

3. The IC structure of claim 2, wherein the first high thermal conductivity layer directly contacts opposing sidewalls of an individual source/drain region in the pair of source/drain regions.

4. The IC structure of claim 2, further comprising:
a plurality of conductive contacts disposed in the first high thermal conductivity layer, wherein the conductive contacts are disposed on the source/drain regions.

5. The IC structure of claim 4, wherein the first high thermal conductivity layer directly contacts opposing sidewalls of the plurality of conductive contacts.

6. The IC structure of claim 1, wherein the second dielectric structure further comprises a first dielectric layer on the first high thermal conductivity layer and a second high thermal conductivity layer on the first dielectric layer, wherein a thermal conductivity of the first dielectric layer is less than that of the first and second high thermal conductivity layers.

7. The IC structure of claim 6, wherein a thickness of the first dielectric layer is less than a thickness of the first high thermal conductivity layer.

8. The IC structure of claim 1, wherein the thermal conductivity of the first high thermal conductivity layer is greater than or equal to about 10 W/m-K.

9. The IC structure of claim 1, wherein the first high thermal conductivity layer comprises one or more of aluminum nitride, boron nitride, yttrium oxide, yttrium aluminum garnet, aluminum oxide, beryllium oxide, silicon carbide, graphene, diamond like carbon, and diamond.

10. An integrated circuit (IC) structure, comprising:
a semiconductor device having a frontside and a backside opposite the frontside, wherein the semiconductor device comprises a gate structure between a pair of source/drain regions;
a first interconnect structure on the frontside of the semiconductor device, wherein the first interconnect structure comprises a plurality of first conductive interconnects electrically coupled to the semiconductor device and disposed in a first dielectric structure; and
a second interconnect structure on the backside of the semiconductor device, wherein the second interconnect structure comprises a plurality of second conductive interconnects disposed in a second dielectric structure, wherein the plurality of second conductive interconnects comprises a plurality of conductive contacts disposed on and electrically coupled to the source/drain regions, wherein the plurality of conductive contacts are disposed in a first high thermal conductivity layer of the second dielectric structure.

11. The IC structure of claim 10, wherein the semiconductor device comprises a channel structure abutting the gate structure and between the pair of source/drain regions, wherein the first high thermal conductivity layer directly contacts the gate structure or the channel structure.

12. The IC structure of claim 10, wherein the second dielectric structure further comprises a dielectric layer on the first high thermal conductivity layer, wherein a thermal conductivity of the first high thermal conductivity layer is greater than that of the dielectric layer.

13. The IC structure of claim 12, wherein the first high thermal conductivity layer has a crystal structure different from that of the dielectric layer.

14. The IC structure of claim 13, wherein the crystal structure of the first high thermal conductivity layer is cubic.

15. The IC structure of claim 12, wherein the second dielectric structure further comprises a second high thermal conductivity layer disposed along a bottom surface of the plurality of conductive contacts.

16. The IC structure of claim 10, wherein the first dielectric structure comprises an etch stop layer disposed between inter-level dielectric (ILD) layers, wherein a thermal conductivity of the first high thermal conductivity layer is greater than that of the etch stop layer.

17. A method for forming an integrated circuit (IC) structure, comprising:
forming a stack of layers over a base substrate, wherein the stack of layers includes an etch stop layer over the base substrate and a lower semiconductor layer on the etch stop layer;
forming a plurality of semiconductor devices on the lower semiconductor layer;
forming a first interconnect structure on a frontside of the plurality of semiconductor devices, wherein the first interconnect structure comprises a plurality of first conductive interconnects disposed in a first dielectric structure;
bonding the first interconnect structure to a carrier substrate;
removing the base substrate, the etch stop layer, and the lower semiconductor layer from over a backside of the plurality of semiconductor devices, where the backside is opposite the frontside; and
forming a first high thermal conductivity layer on the backside of the plurality of semiconductor devices.

18. The method of claim 17, wherein a thermal conductivity of the first high thermal conductivity layer is greater than that of the etch stop layer.

19. The method of claim 17, further comprising:
forming a plurality of conductive contacts in the first high thermal conductivity layer, wherein the conductive contacts contact the semiconductor devices.

20. The method of claim 17, wherein the first high thermal conductivity layer is formed by physical vapor deposition (PVD), chemical vapor deposition (CVD), plasma-enhanced CVD (PECVD), or atomic layer deposition (ALD) at a temperature within a range of about 100 to 400 degrees Celsius.
